(19) United States
(12) Patent Application Publication
(10) Pub. No.: US 2025/0294928 A1
(43) Pub. Date: Sep. 18, 2025

(54) EPITAXIAL DIE ENABLING EASY DETECTION OF ELECTRICAL DEFECTS, SEMICONDUCTOR LIGHT-EMITTING DEVICE USING SAME, AND MANUFACTURING METHODS THEREOF

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,631

(22) PCT Filed: Sep. 18, 2023
(86) PCT No.: PCT/KR2023/014069

§ 371 Date: Oct. 26, 2024

(30) Foreign Application Priority Data
Sep. 19, 2022 (KR) 10-2022-0117788
Dec. 13, 2022 (KR) 10-2022-0173410
Dec. 21, 2022 (KR) 10-2022-0180317
Jan. 3, 2023 (KR) 10-2023-0000590

(51) Int. Cl. H10H 20/831; H01L 21/66; H10H 20/01; H10H 20/84; H10H 20/85; H10H 20/852

(52) U.S. Cl. CPC H10H 20/8314; H01L 22/32; H10H 20/018; H10H 20/032; H10H 20/034; H10H 20/0362; H10H 20/84; H10H 20/8502; H10H 20/852

(57) ABSTRACT

The present invention relates to: an epitaxial die having a structure enabling easy detection of electrical defects in an epitaxial die before an upper wiring process and easy replacement of a defective epitaxial die; a semiconductor light-emitting device using same; and manufacturing methods thereof.

### TECHNICAL FIELD

The present invention relates to an epitaxial die that facilitates detection of electrical defects, a semiconductor light-emitting device using the same, and manufacturing methods thereof.

### BACKGROUND ART

In general, micro light-emitting diode (LED) displays (including mini LED displays) can be classified into micro LED displays with a passive matrix (PM) driving method and micro LED displays with an active matrix (AM) driving method.

Here, PM-driven micro LED displays typically have a sapphire final support substrate, which finally remains, and use sorted thick BGR (Blue, Green, and Red) chips (with both fully fabricated positive and negative electrodes of the LED), which are transferred using a chip die-level process in which either horizontal chips or flip chips can be generally utilized.

In addition, AM-driven micro LED displays typically do not have a sapphire final support substrate, which finally remains, and use unsorted thin BGR (Blue, Green, and Red) chips (with both fully fabricated positive and negative electrodes of the LED), which are transferred using a wafer-level process in which horizontal chips, flip chips, or vertical chips can all be generally utilized.

These conventional typical PM- and AM-driven micro LED displays have the following common issues.

First, when considering the application of vertical chips to reduce chip die size, there is a problem that, unlike flip chips, which allow defects to be immediately confirmed after bonding, in the case of vertical chips, defects can only be confirmed after bonding and subsequent upper wiring.

Further, in terms of a bonding process, higher precision is required in the bonding process due to the reduction in chip die size, and improved bonding strength is required due to the reduction in bonding area.

Further, in terms of a tiling process in which a plurality of unit displays are combined like tiles, there is an issue in which boundaries between the unit displays become distinct when the displays are turned off or show a black screen, and this is more noticeable in the PM driving method compared to the AM driving method. In addition, although many aspects have been improved, there is still an issue in which boundaries are visible on monochromatic screens and still images, and when using thin-film transistor (TFT) glass panels for tiling, the process is challenging due to the risk of glass breakage. Further, due to the tolerance relationship between pixel pitch and tiling boundaries, various issues exist, including the expectation that the tiling process will be difficult to apply to products smaller than 100 inches.

Meanwhile, in the conventional PM-driven micro LED displays, the reduction in chip die size is the greatest challenge. That is, from an aspect ratio perspective, achieving a reduction in chip die size essentially requires decreasing a thickness of a sapphire final support substrate, but the current limit for the thickness of the sapphire final support substrate is about 80 μm to 70 μm, and when the thickness is reduced below 50 μm, a substrate cutting issue occurs. Further, there are complex issues related to chip measurement and classification in this type of micro LED display, and it is expected that flip chips will be mainly used in this type of display rather than horizontal and vertical chips, but when the flip chips are used, high-precision and high-speed bonding processes, as well as materials for them, are separately required.

Further, in conventional AM-driven micro LED displays, in which the final support substrate is not present and chip die size reduction is possible, there are issues related to resolving defects (No Good, NG). That is, the fundamental issues in epitaxial and fab processes, such as yield improvement related to wavelength and electrical characteristics at the chip-on-wafer (COW) level, have not been resolved, and there is difficulty in 100% sorting and removal of defective (NG) chips. In order to address these issues, approaches such as redundancy have been recently attempted, but have not provided a fundamental solution.

### DISCLOSURE

### Technical Problem

The present invention is directed to solving the above-mentioned conventional problems and providing an epitaxial die having a structure capable of easily detecting electrical defects of the epitaxial die and replacing a defective epitaxial die before an upper wiring process, a method of manufacturing a semiconductor light-emitting device using the epitaxial die.

### Technical Solution

The above objective is achieved by a method of manufacturing a semiconductor light-emitting device that facilitates detection of electrical defects, including a first operation of preparing an epitaxial die, which includes a support substrate, a light-emitting part that generates light, a contact electrode that is not exposed to the outside, and a bonding pad layer that is exposed to the outside, and preparing a substrate part in which a first electrode pad and a second electrode pad are formed, a second operation of placing the epitaxial die on the first electrode pad, and bonding and electrically connecting the first electrode pad and the bonding pad layer through a bonding layer, a third operation of separating the support substrate, a fourth operation of exposing the contact electrode, a fifth operation of inspecting electrical defects of the epitaxial die through the exposed contact electrode, and a sixth operation of forming an extension electrode that electrically connects the second electrode pad and the contact electrode.

The above objective is achieved by a semiconductor light-emitting device using an epitaxial die that facilitates detection of electrical defects, including a substrate part in which a first electrode post and a second electrode post are formed through via holes, and a first electrode pad electrically connected to the first electrode post and a second electrode pad electrically connected to the second electrode post are formed, an epitaxial die including a light-emitting part that generates light, a contact electrode exposed to the outside after being transferred onto the substrate part, and a bonding pad layer, a bonding layer that bonds and electrically connects the first electrode pad and the bonding pad layer, and an extension electrode that electrically connects the second electrode pad and the contact electrode exposed to the outside.

The above objective is achieved by a method of manufacturing a semiconductor light-emitting device using an epitaxial die that facilitates detection of electrical defects, including a first operation of preparing an epitaxial die including a support substrate, a light-emitting part that generates light, a contact electrode that is not exposed to the outside, and a bonding pad layer that is exposed to the outside, and preparing a substrate part in which a first electrode post and a second electrode post are formed through via holes, and a first electrode pad electrically connected to the first electrode post and a second electrode pad electrically connected to the second electrode post are formed, a second operation of placing the epitaxial die on the first electrode pad, and bonding and electrically connecting the first electrode pad and the bonding pad layer through a bonding layer, a third operation of separating the support substrate, a fourth operation of exposing the contact electrode, and a fifth operation of forming an extension electrode that electrically connects the second electrode pad and the exposed contact electrode.

The above objective is achieved by an epitaxial die, which facilitates detection of electrical defects, for a semiconductor light-emitting device, including a support substrate, a light-emitting part formed on the support substrate, having one side etched to a predetermined depth, and configured to generate light, an ohmic electrode formed on the light-emitting part and electrically connected to the light-emitting part, a contact electrode formed on the etched one side of the light-emitting part, electrically connected to the light-emitting part, and having a bent part formed to bend and extend from one end portion, a passivation layer that covers the ohmic electrode and the contact electrode, and is partially open to expose a portion of the ohmic electrode, and a bonding pad layer formed on the exposed ohmic electrode to be electrically connected to the ohmic electrode, and exposed to the outside to function as a vertical chip bonding pad, wherein the contact electrode is interposed between the passivation layer and the light-emitting part and is not exposed to the outside.

The above objective is achieved by an epitaxial die, which facilitates detection of electrical defects, for a semiconductor light-emitting device, including a support substrate, a light-emitting part formed on the support substrate, having one side etched to a predetermined depth, and configured to generate light, a first ohmic electrode formed on the light-emitting part and electrically connected to the light-emitting part, a second ohmic electrode formed on the etched one side of the light-emitting part and electrically connected to the light-emitting part, a first passivation layer that covers the first ohmic electrode and the second ohmic electrode, and is partially open to expose a portion of the first ohmic electrode, a contact electrode formed on the exposed first ohmic electrode to be electrically connected to the first ohmic electrode, and having a bent part formed to bend and extend from one end portion, a second passivation layer that covers the first passivation layer and the contact electrode, and a bonding pad layer formed on the second passivation layer to be electrically connected to the second ohmic electrode, and exposed to the outside to function as a vertical chip bonding pad, wherein the contact electrode is interposed between the second passivation layer and the first ohmic electrode and is not exposed to the outside.

The above objective is achieved by a method of manufacturing a semiconductor light-emitting device using an epitaxial die that facilitates detection of electrical defects, including a first operation of preparing an epitaxial die, which includes a support substrate, a light-emitting part that generates light, a contact electrode that has a bent part formed to bend and extend from one end portion and is not exposed to the outside, and a bonding pad layer that is exposed to the outside, and preparing a substrate part in which a first electrode pad and a second electrode pad are formed, a second operation of placing the epitaxial die on the first electrode pad, and bonding and electrically connecting the first electrode pad and the bonding pad layer through a bonding layer, a third operation of separating the support substrate, a fourth operation of exposing the bent part of the contact electrode, a fifth operation of inspecting electrical defects of the epitaxial die through the exposed bent part, and a sixth operation of forming an extension electrode that electrically connects the second electrode pad and the bent part.

### Advantageous Effects

According to the present invention, unlike conventional chip dies in which two electrodes, i.e., a positive electrode and a negative electrode, are exposed to the outside, an epitaxial die of the present invention has a structure in which only one electrode is exposed to the outside, and thus, although the epitaxial die is not electrically sorted, the epitaxial die can be optically sorted, so that defects (NG) can be easily identified initially by a high-speed photoluminescence (PL) measurement method or the like using only optical characteristics (wavelength, full width half maximum (FWHM), intensity, and the like), and electrical defects of the epitaxial die can be easily detected and defective epitaxial dies can be easily repaired or replaced before an upper wiring process.

Further, according to the present invention, it is possible to simultaneously satisfy both the advantage of a mini light-emitting diode (LED) manufacturing process, such as ease of defect classification, and low process and facility investment costs due to the use of existing general-purpose transfer equipment as it is, and the advantage of a micro LED manufacturing process, such as a dramatic reduction in thickness and a reduction in chip die size by removing a sapphire final support substrate, thereby improving light output.

Further, according to the present invention, an epitaxial die of the present invention has the advantage that a process of forming a p-ohmic contact electrode or an n-ohmic contact electrode, which requires high-temperature heat treatment of 300° C. or higher, is completed in the operation of manufacturing the epitaxial die, so that the epitaxial die of the present invention does not require a high-temperature heat treatment process after transfer.

Further, according to the present invention, an epitaxial die of the present invention has the advantage of having a sapphire final support substrate attached, which can be removed after being transferred onto a targeted wafer, thereby enabling the die to be repositioned through conventional chip die transfer processes such as pick-and-place and replace.

Meanwhile, the effects of the present invention are not limited to the above-mentioned effects, and various effects may be included within the scope which is apparent to those skilled in the art from content to be described below.

### DESCRIPTION OF DRAWINGS

FIG. 1 is a flowchart illustrating a method of manufacturing a semiconductor light-emitting device that facilitates detection of electrical defects according to a first embodiment of the present invention.

FIG. 2 illustrates a process of manufacturing the semiconductor light-emitting device that facilitates detection of electrical defects according to the first embodiment of the present invention.

FIG. 3 illustrates electrode posts formed in a substrate part of the semiconductor light-emitting device that facilitates detection of electrical defects according to the first embodiment of the present invention.

FIG. 4 is a flowchart illustrating a method of manufacturing a semiconductor light-emitting device that facilitates detection of electrical defects according to a second embodiment of the present invention.

FIG. 5 illustrates a process of manufacturing the semiconductor light-emitting device that facilitates detection of electrical defects according to the second embodiment of the present invention.

FIG. 6 illustrates electrode posts formed in a substrate part of the semiconductor light-emitting device that facilitates detection of electrical defects according to the second embodiment of the present invention.

FIG. 7 is a flowchart illustrating a method of manufacturing a semiconductor light-emitting device that facilitates detection of electrical defects according to a third embodiment of the present invention.

FIG. 8 illustrates a process of manufacturing the semiconductor light-emitting device that facilitates detection of electrical defects according to the third embodiment of the present invention.

FIG. 9 illustrates electrode posts formed in a substrate part of the semiconductor light-emitting device that facilitates detection of electrical defects according to the third embodiment of the present invention.

FIG. 10 is a flowchart illustrating a method of manufacturing a semiconductor light-emitting device that facilitates detection of electrical defects according to a fourth embodiment of the present invention.

FIG. 11 illustrates a process of manufacturing the semiconductor light-emitting device that facilitates detection of electrical defects according to the fourth embodiment of the present invention.

FIG. 12 illustrates electrode posts formed in a substrate part of the semiconductor light-emitting device that facilitates detection of electrical defects according to the fourth embodiment of the present invention.

FIG. 13 is a flowchart illustrating a method of manufacturing a semiconductor light-emitting device that facilitates detection of electrical defects according to a fifth embodiment of the present invention.

FIG. 14 illustrates a process of manufacturing the semiconductor light-emitting device that facilitates detection of electrical defects according to the fifth embodiment of the present invention.

FIG. 15 illustrates electrode posts formed in a substrate part of the semiconductor light-emitting device that facilitates detection of electrical defects according to the fifth embodiment of the present invention.

FIG. 16 is a flowchart illustrating a method of manufacturing a semiconductor light-emitting device that facilitates detection of electrical defects according to a sixth embodiment of the present invention.

FIGS. 17 and 18 illustrate a process of manufacturing the semiconductor light-emitting device that facilitates detection of electrical defects according to the sixth embodiment of the present invention.

FIG. 19 illustrates electrode posts formed in a substrate part of the semiconductor light-emitting device that facilitates detection of electrical defects according to the sixth embodiment of the present invention.

FIG. 20 is a flowchart illustrating a method of manufacturing a semiconductor light-emitting device that facilitates detection of electrical defects according to a seventh embodiment of the present invention.

FIG. 21 illustrates a process of manufacturing the semiconductor light-emitting device that facilitates detection of electrical defects according to the seventh embodiment of the present invention.

FIG. 22 illustrates electrode posts formed in a substrate part of the semiconductor light-emitting device that facilitates detection of electrical defects according to the seventh embodiment of the present invention.

FIG. 23 illustrates an overall view of an epitaxial die that facilitates detection of electrical defects according to an eighth embodiment of the present invention.

FIG. 24 illustrates that the epitaxial die that facilitates detection of electrical defects according to the eighth embodiment of the present invention includes a sacrificial release layer and a bonding layer when emitting red light.

FIG. 25 is a flowchart illustrating a method of manufacturing a semiconductor light-emitting device using the epitaxial die that facilitates detection of electrical defects according to the eighth embodiment of the present invention.

FIG. 26 illustrates a process of manufacturing the semiconductor light-emitting device using the epitaxial die that facilitates detection of electrical defects according to the eighth embodiment of the present invention.

FIG. 27 illustrates an overall view of an epitaxial die that facilitates detection of electrical defects according to a ninth embodiment of the present invention.

FIG. 28 illustrates that the epitaxial die that facilitates detection of electrical defects according to the ninth embodiment of the present invention includes a sacrificial release layer and a bonding layer when emitting red light.

FIG. 29 is a flowchart illustrating a method of manufacturing a semiconductor light-emitting device using the epitaxial die that facilitates detection of electrical defects according to the ninth embodiment of the present invention.

FIG. 30 illustrates a process of manufacturing the semiconductor light-emitting device using the epitaxial die that facilitates detection of electrical defects according to the ninth embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even when shown in different drawings.

In addition, in describing the embodiments of the present invention, when detailed descriptions of related known structures or functions may obscure the gist of the present invention, the detailed description thereof will be omitted.

In addition, terms such as “first,” “second,” “A,” “B,” “(a),” “(b),” and the like may be used herein to describe components of the embodiments of the present invention. These terms are not used to define an essence, order, or sequence of a corresponding component but merely to distinguish the corresponding component from other component(s).

The present invention relates to a method of manufacturing a semiconductor light-emitting device using an epitaxial die, which emits blue, green, or red light and facilitates detection of electrical defects. In the present invention, a semi-finished light source die with a size less than or equal to that of a mini light-emitting diode (LED), which can be sorted and has the following characteristics, is defined as the epitaxial die of the present invention.

First, unlike conventional chip dies in which two electrodes, i.e., a positive electrode and a negative electrode, are both exposed to the outside, the epitaxial die of the present invention has a structure in which only one electrode is exposed to the outside. Accordingly, in the epitaxial die of the present invention, since only one (contact electrode) of two electrodes is exposed to the outside, even though the epitaxial die is not electrically sorted, the epitaxial die can be optically sorted, so that defects (NG) can be easily identified initially by a high-speed photoluminescence (PL) measurement method or the like using only optical characteristics (wavelength, full width half maximum (FWHM), intensity, and the like), and electrical defects of the epitaxial die can be easily detected and defective epitaxial dies can be easily replaced before an upper wiring process.

Second, in the epitaxial die of the present invention, a process of forming a p-ohmic contact electrode or an n-ohmic contact electrode, which requires high-temperature heat treatment of 300° C. or higher, is completed in the operation of manufacturing the epitaxial die. Accordingly, the epitaxial die of the present invention has the advantage of not requiring a high-temperature heat treatment process after transfer.

Third, the epitaxial die of the present invention includes a sapphire final support substrate attached thereto, which is removed after transfer. Accordingly, the epitaxial die of the present invention has the advantage of being repositionable through conventional chip die transfer processes such as pick-and-place and replace.

That is, the epitaxial die of the present invention can simultaneously satisfy both the advantage of a mini light-emitting diode (LED) manufacturing process, such as ease of defect classification, and low process and facility investment costs due to the use of existing general-purpose transfer equipment as it is, and the advantage of a micro LED manufacturing process, such as a dramatic reduction in thickness and a reduction in chip die size by removing a final support substrate, which is the final substrate, thereby improving light output.

Further, the semiconductor light-emitting device of the present invention may be formed as a chip-on-board (COB) in which individual chips or epitaxial die units are directly transferred and connected to a substrate (such as a semiconductor wafer, a printed circuit board (PCB), or thin-film transistor (TFT) glass) on which circuit wiring and driving element regions are completed, a package-on-board (POB) in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using the intermediate temporary substrate on which circuit wiring and driving element regions are not completed, but is not limited thereto, and will be described herein as being formed as the COB type for convenience of description.

Meanwhile, in the present invention, the substrate onto which the epitaxial die is transferred may include through-silicon vias (TSVs), through-glass vias (TGVs), through-sapphire vias (TSaVs), through-AAO vias (TAVs), through-zirconia vias (TZVs), through-polyimide vias (TPoVs), through-resin vias (TRVs), and the like, in which via holes are formed first, and then electrode posts are formed in the corresponding via holes.

Hereinafter, with reference to the accompanying drawings, a method (S10) of manufacturing a semiconductor light-emitting device according to a first embodiment of the present invention will be described in detail.

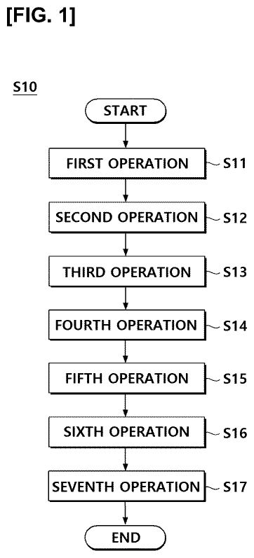

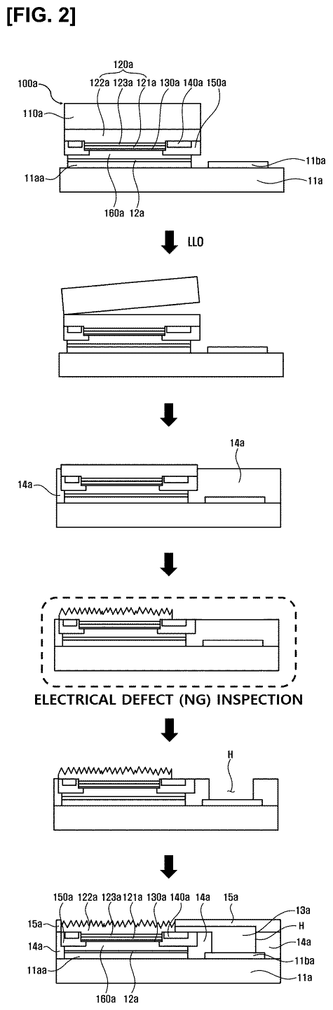

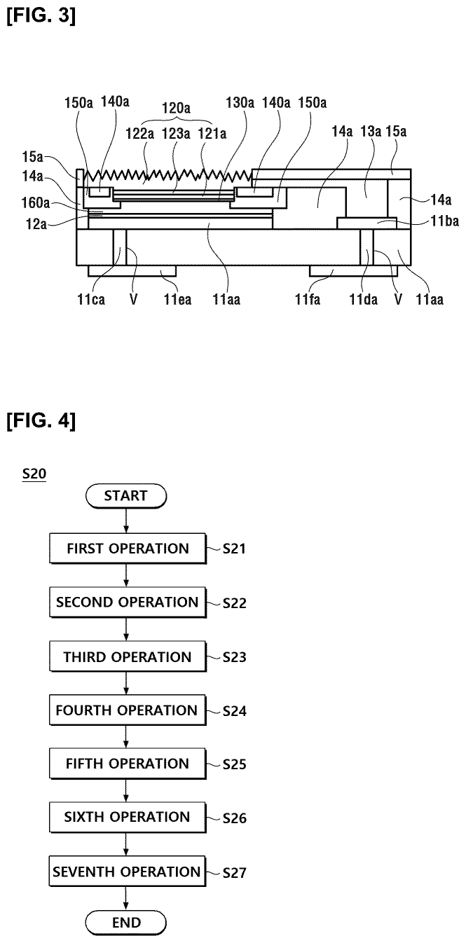

FIG. 1 is a flowchart illustrating a method of manufacturing a semiconductor light-emitting device that facilitates detection of electrical defects according to the first embodiment of the present invention, FIG. 2 illustrates a process of manufacturing the semiconductor light-emitting device that facilitates detection of electrical defects according to the first embodiment of the present invention, and FIG. 3 illustrates electrode posts formed on a substrate part of the semiconductor light-emitting device that facilitates detection of electrical defects according to the first embodiment of the present invention.

As shown in FIGS. 1 and 2, the method (S10) of manufacturing the semiconductor light-emitting device according to the first embodiment of the present invention includes a first operation S11, a second operation S12, a third operation S13, a fourth operation S14, a fifth operation S15, a sixth operation S16, and a seventh operation S17. However, it is of course possible to change the order of the processes shown in FIGS. 1 and 2.

The first operation S11 is an operation of preparing an epitaxial die 100a for a semiconductor light-emitting device according to the first embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 100a (e.g., the polarity of a bonding pad layer 160a).

Further, as shown in FIG. 3, when the substrate part 11aa has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

In addition, the epitaxial die 100a for a semiconductor light-emitting device according to the first embodiment of the present invention includes a final support substrate 110a, a light-emitting part 120a that generates light, a first ohmic electrode 130a, a contact electrode 140a that is not exposed to the outside, a passivation layer 150a, and the bonding pad layer 160a that is exposed to the outside.

The final support substrate 110a supports the light-emitting part 120a, the first ohmic electrode 130a, the contact electrode 140a, the passivation layer 150a, and the bonding pad layer 160a, and a sapphire initial growth substrate may be used thereas. The light-emitting part 120a to be described below may be epitaxially grown on the final support substrate 110a.

Meanwhile, in the present invention, the final support substrate 110a that supports the light-emitting part 120a, the first ohmic electrode 130a, the contact electrode 140a, the passivation layer 150a, and the bonding pad layer 160a is an initial growth substrate on which the light-emitting part 120a is grown.

The light-emitting part 120a generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, may be epitaxially grown on the final support substrate 110a, which is an initial growth substrate, by being placed in appropriate positions and sequences.

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 120a includes a first semiconductor region 121a (e.g., a p-type semiconductor region), an active region 123a (e.g., multi-quantum wells (MQWs)), and a second semiconductor region 122a (e.g., an n-type semiconductor region), and the light-emitting part 120a may have a structure in which the second semiconductor region 122a, the active region 123a, and the first semiconductor region 121a are epitaxially grown in that order on the final support substrate 110a, and ultimately, may have an overall thickness typically ranging from about 5.0 to 8.0 μm, including multiple layers of group III nitrides, but the present invention is not limited thereto.

Each of the first semiconductor region 121a, the active region 123a, and the second semiconductor region 122a may be formed as either a single layer or multiple layers, and although not shown in the drawing, necessary layers, such as buffer regions, may be added before epitaxially growing the light-emitting part 120a on the sapphire initial growth substrate to ensure the high quality of the epitaxially grown light-emitting part 120a. For example, the buffer regions may include a nucleation layer and a compliant layer composed of an un-doped semiconductor region to relieve stress and improve thin-film quality and typically have a thickness of about 4.0 μm. In addition, when the final support substrate 110a is removed using a laser lift-off (LLO) technique, a sacrificial layer may be provided between the nucleation layer and the un-doped semiconductor region, and a seed layer may function as the sacrificial layer.

The second semiconductor region 122a has a second conductivity type (n-type), and is formed on the final support substrate 110a. The second semiconductor region 122a may have a thickness of 2.0 to 3.5 μm.

The active region 123a generates light using the recombination of electrons and holes and is formed on the second semiconductor region 122a. The active region 123a may have a multi-layer structure primarily composed of indium gallium nitride (InGaN) and gallium nitride (GaN) semiconductors, and may have a thickness of several tens of nanometers (nm).

The first semiconductor region 121a has a first conductivity type (p-type), and is formed on the active region 123a. The first semiconductor region 121a may have a multi-layer structure primarily composed of aluminum gallium nitride (AlGaN) and gallium nitride (GaN) semiconductors, may have a thickness ranging from several tens of nanometers (nm) to several micrometers (μm), and includes a top surface having gallium (Ga) polarity.

That is, the active region 123a is interposed between the first semiconductor region 121a and the second semiconductor region 122a, and light is generated when holes in the first semiconductor region 121a, which is a p-type semiconductor region, and electrons in the second semiconductor region 122a, which is an n-type semiconductor region, recombine in the active region 123a.

At this time, the light-emitting part 120a formed on the final support substrate 110a may have a side portion, i.e., one or both sides, etched to a predetermined depth (i.e., both side surfaces may have a mesa-etched shape), and when viewed from above, all of upper, lower, left, and right edges may have a mesa-etched shape. Here, the predetermined depth may refer to a depth up to the second semiconductor region 122a, but the present invention is not limited thereto. Meanwhile, the surface of the etched portion of the second semiconductor region 122a of the light-emitting part 120a has gallium (Ga) polarity.

The first ohmic electrode 130a is electrically connected to the first semiconductor region 121a of the light-emitting part 120a and is formed on the first semiconductor region 121a to cover and come into surface contact with an upper surface of the first semiconductor region 121a. At this time, the first semiconductor region 121a is electrically connected to the first ohmic electrode 130a through a p-ohmic contact.

The contact electrode 140a is electrically connected to the second semiconductor region 122a of the light-emitting part 120a, and may be formed at the etched side portion, i.e., one side or both sides, of the second semiconductor region 122a.

The first ohmic electrode 130a and the contact electrode 140a may be basically formed of materials that have high transparency or reflectance and excellent electrical conductivity, but the present invention is not limited thereto. The materials of the first ohmic electrode 130a may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination.

Meanwhile, the materials of the contact electrode 140a may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, which may be used alone or in combination.

At this time, as described above, the etched portion of the second semiconductor region 122a has a gallium (Ga) polar surface, and the gallium (Ga) polar surface is electrically connected to the contact electrode 140a through an n-ohmic contact.

The passivation layer 150a covers a side portion of the first ohmic electrode 130a from the etched portion of the light-emitting part 120a via the contact electrode 140a, and when both sides of the light-emitting part 120a are etched, the passivation layer 150a may have a shape that covers one side of the first ohmic electrode 130a from the etched portion on one side of the light-emitting part 120a via the contact electrode 140a, and covers the other side of the first ohmic electrode 130a from the etched portion on the other side of the light-emitting part 120a via the contact electrode 140a. Due to such a shape of the passivation layer 150a, the contact electrode 140a is interposed between the passivation layer 150a and the light-emitting part 120a and thus is not exposed.

The passivation layer 150a may be implemented with electrically insulating materials, and may include, for example, a single layer or multiple layers including at least one material from among silicon oxide, silicon nitride, metallic oxides including Al₂O₃, and organic insulators.

The bonding pad layer 160a functions as a vertical chip die bonding pad, and is formed on the first ohmic electrode 130a and the passivation layer 150a to be electrically connected to the first ohmic electrode 130a. At this time, the bonding pad layer 160a is electrically connected to the first ohmic electrode 130a through a p-ohmic contact and is exposed to the outside, thereby functioning as a positive electrode.

The bonding pad layer 160a may basically include low melting point metals and noble metals such as gold (Au), silver (Ag), copper (Cu), and palladium (Pd), but the present invention is not limited thereto. In addition, the low melting point metals of the bonding pad layer 160a may be formed of metals such as In, Sn, Zn, and Pb alone or alloys including these metals.

Accordingly, the epitaxial die 100a for a semiconductor light-emitting device according to the first embodiment of the present invention has a form in which the contact electrode 140a, which is a negative electrode, is interposed between the passivation layer 150a and the light-emitting part 120a, and thus is not exposed, and only the bonding pad layer 160a, which functions as a positive electrode, is exposed to the outside.

The second operation S12 is an operation of placing the epitaxial die 100a upside down on the first electrode pad 11aa, and electrically connecting the first electrode pad 11aa and the bonding pad layer 160a by bonding the first electrode pad 11aa and the bonding pad layer 160a through a bonding layer 12a. At this time, the placement and bonding of the epitaxial die 100a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 100a, (2) an epitaxial die 100a with an ultra-small size of less than 50 μm×50 μm, and (3) an epitaxial die 100a having a self-assembly structure, additional masking media (such as a photoresist, ceramics (like glass, quartz, and alumina), or an invar fine metal mask (FMM)) or processes may be employed before the placement and bonding of the epitaxial die 100a.

The third operation S13 is an operation of separating the final support substrate 110a of the epitaxial die 100a. At this time, in the third operation S13, the final support substrate 110a may be separated from the light-emitting part 120a, i.e., the second semiconductor region 122a, using an LLO technique to expose an upper surface of the second semiconductor region 122a. Here, the LLO technique is a technique of separating the final support substrate 110a from the epitaxially grown layers by irradiating a rear surface of the transparent final support substrate 110a with an ultraviolet (UV) laser beam having a uniform output and beam profile, and a single wavelength.

The fourth operation S14 is an operation of etching one side of the light-emitting part 120a to expose the contact electrode 140a. That is, the fourth operation S14 is an operation of etching one side of the second semiconductor region 122a through dry etching or wet etching to expose the contact electrode 140a, which was interposed between the second semiconductor region 122a and the passivation layer 150a and was not exposed.

Meanwhile, in the fourth operation S14, a surface texture pattern of a predetermined shape or an irregular shape may be formed on an upper surface of the light-emitting part 120a, i.e., the upper surface of the second semiconductor region 122a, of the upside-down epitaxial die 100a to extract as much light generated in the active region 123a into the air as possible.

Meanwhile, before an electrical defect inspection is performed in the fifth operation S15, a mold part 14a surrounding the epitaxial die 100a may be formed in the fourth operation S14 such that the upper surface of the light-emitting part 120a, i.e., the upper surface of the second semiconductor region 122a, is exposed. At this time, the mold part 14a may be made of materials that enable LDS or LDI, allowing laser drilling in the sixth operation S16 to be described below. In addition, when the mold part 14a is not formed in the fourth operation S14, the contact electrode may be exposed after a photoresist (PR) is applied.

The fifth operation S15 is an operation of inspecting electrical defects of the epitaxial die 100a through the exposed contact electrode 140a, and repairing the semiconductor light-emitting device by replacing the corresponding epitaxial die 100a when the electrical defect inspection result indicates that the epitaxial die 100a is electrically defective. That is, in the present invention, electrical defects in the epitaxial die 100a can be detected and the defective epitaxial die 100a can be easily replaced before an upper wiring process is performed to form the extension electrode 13a.

The sixth operation S16 is an operation of forming the extension electrode 13a that electrically connects the second electrode pad 11ba and the contact electrode 140a. Meanwhile, when the mold part 14a is not formed in the fourth operation S14, the mold part 14a surrounding the epitaxial die 100a may be formed in the sixth operation S16, following the electrical defect inspection. That is, when the mold part 14a is formed after the electrical defect inspection in the fifth operation S15, there is an effect that the semiconductor light-emitting device is more easily repaired.

More specifically, in the sixth operation S16, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 140a, thereby electrically connecting the contact electrode 140a and the second electrode pad 11ba.

The seventh operation S17 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S20) of manufacturing a semiconductor light-emitting device according to a second embodiment of the present invention will be described in detail.

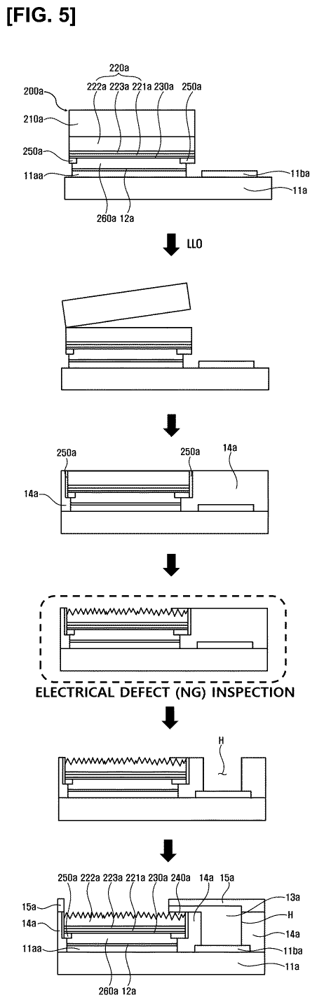

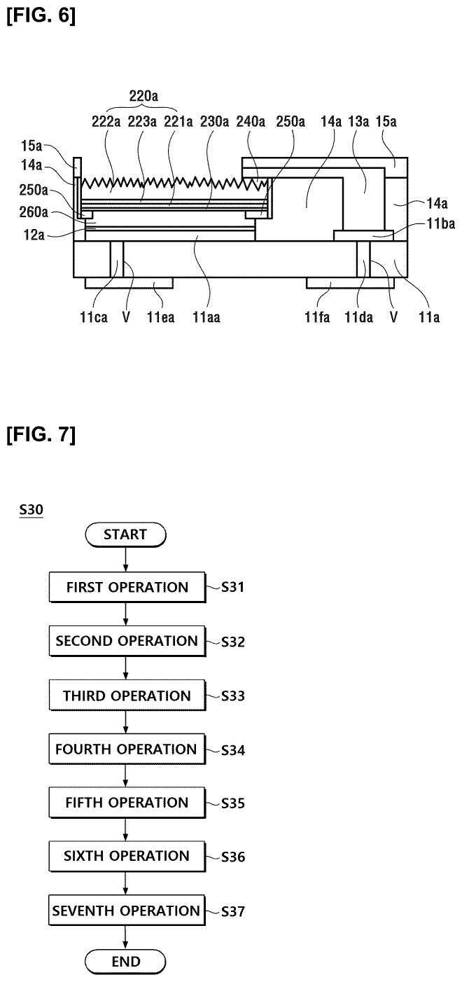

FIG. 4 is a flowchart illustrating a method of manufacturing a semiconductor light-emitting device that facilitates detection of electrical defects according to the second embodiment of the present invention, FIG. 5 illustrates a process of manufacturing the semiconductor light-emitting device that facilitates detection of electrical defects according to the second embodiment of the present invention, and FIG. 6 illustrates electrode posts formed in a substrate part of the semiconductor light-emitting device that facilitates detection of electrical defects according to the second embodiment of the present invention.

As shown in FIGS. 4 and 5, the method (S20) of manufacturing the semiconductor light-emitting device according to the second embodiment of the present invention includes a first operation S21, a second operation S22, a third operation S23, a fourth operation S24, a fifth operation S25, a sixth operation S26, and a seventh operation S27. However, it is of course possible to change the order of the processes shown in FIGS. 4 and 5.

The first operation S21 is an operation of preparing an epitaxial die 200a for a semiconductor light-emitting device according to the second embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 200a (e.g., the polarity of a bonding pad layer 260a).

Further, as shown in FIG. 6, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

In addition, the epitaxial die 200a for a semiconductor light-emitting device according to the second embodiment of the present invention includes a final support substrate 210a, a light-emitting part 220a that generates light, a first ohmic electrode 230a, a passivation layer 250a, and the bonding pad layer 260a that is exposed to the outside.

The final support substrate 210a supports the light-emitting part 220a, the first ohmic electrode 230a, a contact electrode 240a, the passivation layer 250a, and the bonding pad layer 260a, and a sapphire initial growth substrate may be used thereas. The light-emitting part 220a to be described below may be epitaxially grown on the final support substrate 210a.

Meanwhile, in the present invention, the final support substrate 210a that supports the light-emitting part 220a, the first ohmic electrode 230a, the contact electrode 240a, the passivation layer 250a, and the bonding pad layer 260a is an initial growth substrate on which the light-emitting part 220a is grown.

The light-emitting part 220a generates light, and details of a first semiconductor region 221a, a second semiconductor region 222a, and an active region 223a are the same as those of the above-described method (S10) of manufacturing the semiconductor light-emitting device that facilitates detection of electrical defects according to the first embodiment of the present invention, and thus redundant descriptions will be omitted.

The first ohmic electrode 230a is electrically connected to the first semiconductor region 221a of the light-emitting part 220a and is formed on the first semiconductor region 221a to cover and come into surface contact with an upper surface of the first semiconductor region 221a. At this time, the first semiconductor region 221a is electrically connected to the first ohmic electrode 230a through a p-ohmic contact.

The first ohmic electrode 230a may be basically formed of materials that have high transparency or reflectance and excellent electrical conductivity, but the present invention is not limited thereto. The materials of the first ohmic electrode 230a may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination.

The passivation layer 250a covers a side portion of the first ohmic electrode 230a, and may have a shape that covers one side and the other side of the first ohmic electrode 230a.

The passivation layer 250a may be implemented with electrically insulating materials, and may include, for example, a single layer or multiple layers including at least one material from among silicon oxide, silicon nitride, metallic oxides including Al₂O₃, and organic insulators.

The bonding pad layer 260a functions as a vertical chip die bonding pad, and is formed on the first ohmic electrode 230a and the passivation layer 250a to be electrically connected to the first ohmic electrode 230a. At this time, the bonding pad layer 260a is electrically connected to the first ohmic electrode 230a, is exposed to the outside, and functions as a positive electrode.

The bonding pad layer 260a may basically include low melting point metals and noble metals such as gold (Au), silver (Ag), copper (Cu), and palladium (Pd), but the present invention is not limited thereto. In addition, the low melting point metals of the bonding pad layer 260a may be formed of metals such as In, Sn, Zn, and Pb alone or alloys including these metals.

Meanwhile, in the epitaxial die 200a for a semiconductor light-emitting device according to the second embodiment of the present invention, the contact electrode 240a is not formed because the contact electrode 240a is formed and exposed during the manufacturing process of the semiconductor light-emitting device. As a result, only the bonding pad layer 260a, which functions as a positive electrode, is exposed to the outside.

The second operation S22 is an operation of placing the epitaxial die 200a upside down on the first electrode pad 11aa, and electrically connecting the first electrode pad 11aa and the bonding pad layer 260a by bonding the first electrode pad 11aa and the bonding pad layer 260a through a bonding layer 12a. At this time, the placement and bonding of the epitaxial die 200a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 200a, (2) an epitaxial die 200a with an ultra-small size of less than 50 μm×50 μm, and (3) an epitaxial die 200a having a self-assembly structure, additional masking media (such as a photoresist, ceramics (like glass, quartz, and alumina), or an invar FMM) or processes may be employed before the placement and bonding of the epitaxial die 200a.

The third operation S23 is an operation of separating the final support substrate 210a of the epitaxial die 200a. At this time, in the third operation S23, the final support substrate 210a may be separated from the light-emitting part 220a, i.e., the second semiconductor region 222a, using an LLO technique to expose an upper surface of the second semiconductor region 222a. Here, the LLO technique is a technique of separating the final support substrate 210a from the epitaxially grown layers by irradiating a rear surface of the transparent final support substrate 210a with a UV laser beam having a uniform output and beam profile, and a single wavelength.

The fourth operation S24 is an operation of forming and exposing the contact electrode 240a on an upper surface of the light-emitting part 220a. That is, the contact electrode 240a is electrically connected to the second semiconductor region 222a of the light-emitting part 220a, and may be formed on one side of the upper surface of the second semiconductor region 222a.

The contact electrode 240a may be basically formed of materials that have high transparency or reflectance and excellent electrical conductivity, but is not limited thereto, and the materials of the contact electrode 240a may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, which may be used alone or in combination.

Meanwhile, in the fourth operation S24, a surface texture pattern of a predetermined shape or an irregular shape may be formed on the upper surface of the light-emitting part 220a, i.e., the upper surface of the second semiconductor region 222a, of the upside-down epitaxial die 200a to extract as much light generated in the active region 223a into the air as possible.

Meanwhile, before an electrical defect inspection is performed in the fifth operation S25, a mold part 14a surrounding the epitaxial die 200a may be formed in the fourth operation S24 such that the upper surface of the light-emitting part 220a, i.e., the upper surface of the second semiconductor region 222a, is exposed. At this time, the mold part 14a may be made of materials that enable LDS or LDI, allowing laser drilling in the sixth operation S26 to be described below. In addition, when the mold part 14a is not formed in the fourth operation S24, the contact electrode may be exposed after a photoresist (PR) is applied.

The fifth operation S25 is an operation of inspecting electrical defects of the epitaxial die 200a through the exposed contact electrode 240a, and repairing the semiconductor light-emitting device by replacing the corresponding epitaxial die 200a when the electrical defect inspection result indicates that the epitaxial die 200a is electrically defective. That is, in the present invention, electrical defects in the epitaxial die 200a can be detected and the defective epitaxial die 200a can be easily replaced before an upper wiring process is performed to form an extension electrode 13a.

The sixth operation S26 is an operation of forming the extension electrode 13a that electrically connects the second electrode pad 11ba and the contact electrode 240a. Meanwhile, when the mold part 14a is not formed in the fourth operation S24, the mold part 14a surrounding the epitaxial die 200a may be formed in the sixth operation S26, following the electrical defect inspection. That is, when the mold part 14a is formed after the electrical defect inspection in the fifth operation S25, there is an effect that the semiconductor light-emitting device is more easily repaired.

More specifically, in the sixth operation S26, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 240a, thereby electrically connecting the contact electrode 240a and the second electrode pad 11ba.

The seventh operation S27 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S30) of manufacturing a semiconductor light-emitting device according to a third embodiment of the present invention will be described in detail.

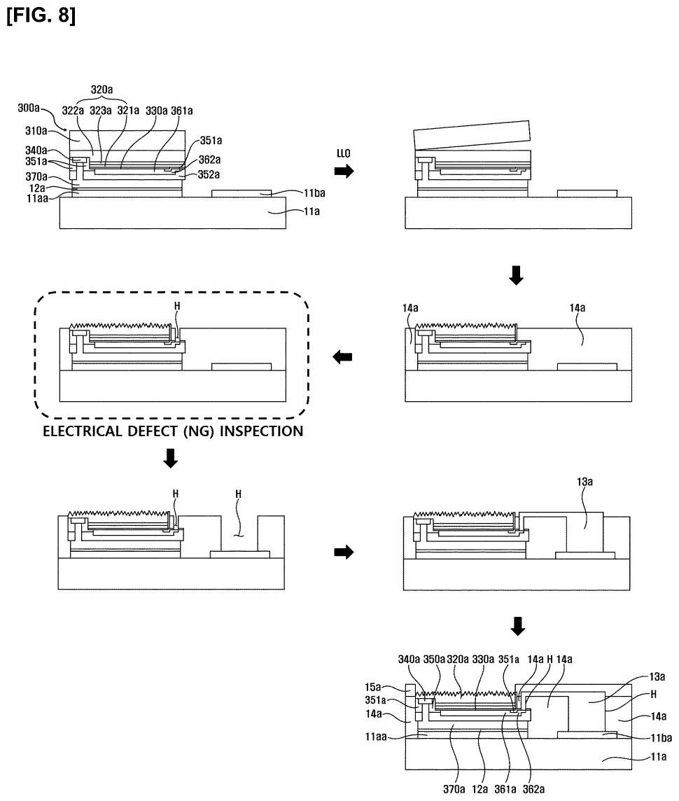

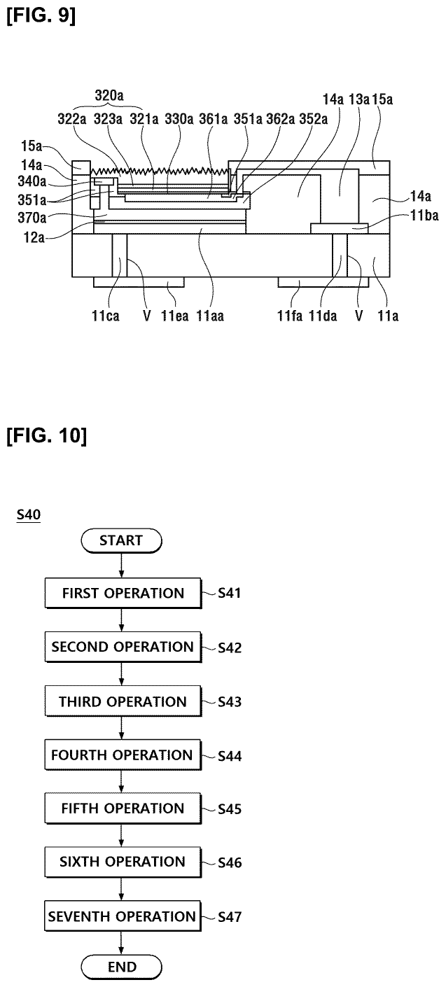

FIG. 7 is a flowchart illustrating a method of manufacturing a semiconductor light-emitting device that facilitates detection of electrical defects according to the third embodiment of the present invention, FIG. 8 illustrates a process of manufacturing the semiconductor light-emitting device that facilitates detection of electrical defects according to the third embodiment of the present invention, and FIG. 9 illustrates electrode posts formed in a substrate part of the semiconductor light-emitting device that facilitates detection of electrical defects according to the third embodiment of the present invention.

As shown in FIGS. 7 and 8, the method (S30) of manufacturing the semiconductor light-emitting device according to the third embodiment of the present invention includes a first operation S31, a second operation S32, a third operation S33, a fourth operation S34, a fifth operation S35, a sixth operation S36, and a seventh operation S37. However, it is of course possible to change the order of the processes shown in FIGS. 7 and 8.

The first operation S31 is an operation of preparing an epitaxial die 300a for a semiconductor light-emitting device according to the third embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 300a (e.g., the polarity of a bonding pad layer 370a). Further, as shown in FIG. 9, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

In addition, the epitaxial die 300a for a semiconductor light-emitting device according to the third embodiment of the present invention includes a final support substrate 310a, a light-emitting part 320a that generates light, a first ohmic electrode 330a, a second ohmic electrode 340a, a first passivation layer 351a, a contact electrode 360a that is not exposed to the outside, a second passivation layer 352a, and the bonding pad layer 370a that is exposed to the outside.

The final support substrate 310a supports the light-emitting part 320a, the first ohmic electrode 330a, the second ohmic electrode 340a, the first passivation layer 351a, the contact electrode 360a, the second passivation layer 352a, and the bonding pad layer 370a, and a sapphire initial growth substrate may be used thereas. The light-emitting part 320a to be described below may be epitaxially grown on the final support substrate 310a.

Meanwhile, in the present invention, the final support substrate 310a, which supports the light-emitting part 320a, the first ohmic electrode 330a, the second ohmic electrode 340a, the first passivation layer 351a, the contact electrode 360a, the second passivation layer 352a, and the bonding pad layer 370a, is an initial growth substrate on which the light-emitting part 320a is grown.

The light-emitting part 320a generates light, and details of a first semiconductor region 321a, a second semiconductor region 322a, and an active region 323a are the same as those of the above-described method (S10) of manufacturing the semiconductor light-emitting device that facilitates detection of electrical defects according to the first embodiment of the present invention, and thus redundant descriptions will be omitted.

At this time, one side of the light-emitting part 320a formed on the final support substrate 310a may have a shape etched to a predetermined depth (i.e., one side may have a mesa-etched shape), and here, the predetermined depth may refer to a depth up to the second semiconductor region 322a, but the present invention is not limited thereto. Meanwhile, the surface of the etched portion of the second semiconductor region 322a of the light-emitting part 320a has gallium (Ga) polarity.

The first ohmic electrode 330a is electrically connected to the first semiconductor region 321a of the light-emitting part 320a and is formed on the first semiconductor region 321a to cover and come into surface contact with an upper surface of the first semiconductor region 321a. At this time, the first semiconductor region 321a is electrically connected to the first ohmic electrode 330a through a p-ohmic contact.

The second ohmic electrode 340a is electrically connected to the second semiconductor region 322a of the light-emitting part 320a and is formed at the etched portion on one side of the second semiconductor region 322a.

The first ohmic electrode 330a and the second ohmic electrode 340a may be formed of materials that essentially have high transparency and/or reflectance and excellent electrical conductivity, but the present invention is not limited thereto. The materials of the first ohmic electrode 330a may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination with the above-described optically transparent materials. Meanwhile, the materials of the second ohmic electrode 340a may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, which may be used alone or in combination with above-described metals.

At this time, as described above, the etched portion of the second semiconductor region 322a has a gallium (Ga) polar surface, and the gallium (Ga) polar surface is electrically connected to the second ohmic electrode 340a through an n-ohmic contact.

The first passivation layer 351a covers one side of the first ohmic electrode 330a from the etched portion on one side of the light-emitting part 320a via the second ohmic electrode 340a, and covers the other side of the first ohmic electrode 330a from the other side of the light-emitting part 320a. The first passivation layer 351a may have a shape that covers one side and the other side of the first ohmic electrode 330a and may thus have a shape that exposes a portion of the first ohmic electrode.

The first passivation layer 351a may be implemented with electrically insulating materials, and may include, for example, a single layer or multiple layers including at least one material from among silicon oxide, silicon nitride, metallic oxides including Al₂O₃, and organic insulators.

The contact electrode 360a is electrically connected to the first ohmic electrode 330a and formed on the first ohmic electrode 330a exposed between gaps in the first passivation layer 351a. The contact electrode 360a includes a base part 361a and an extension part 362a that is formed to extend from an end portion of the base part 361a to the other side (i.e., the side opposite to where the second ohmic electrode 340a is formed) of the light-emitting part 320a and is placed between the first passivation layer 351a and the second passivation layer 352a. At this time, the extension part 362a may be formed to be stepped by being partially bent.

The materials of the contact electrode 360a are not limited as long as they have strong adhesion to the first ohmic electrode 330a, but may include Ti, TiN, Cr, CrN, V, VN, NiCr, Al, Rh, Pt, Ni, Pd, Ru, Cu, Ag, Au, and the like.

The second passivation layer 352a covers the first passivation layer 351a and the contact electrode 360a, and here, an end portion on the other side (i.e., the side opposite to where the second ohmic electrode 340a is formed) of the contact electrode 360a may be partially etched, and the second passivation layer 352a may cover one end portion of the contact electrode 360a from the etched portion of the other end portion of the contact electrode 360a via the contact electrode 360a to prevent the contact electrode 360a from being exposed to the outside. Due to the shape of the second passivation layer 352a that encloses the contact electrode 360a in this manner, the contact electrode 360a is interposed between the second passivation layer 352a and the first ohmic electrode 330a and thus is not exposed.

The second passivation layer 352a may be implemented with electrically insulating materials, and may include, for example, a single layer or multiple layers including at least one material from among silicon oxide, silicon nitride, metallic oxides including Al₂O₃, and organic insulators.

The bonding pad layer 370a functions as a vertical chip die bonding pad, and is formed on the second passivation layer 352a to be electrically connected to the second ohmic electrode 340a. At this time, the bonding pad layer 370a is electrically connected to the second ohmic electrode 340a, is exposed to the outside, and functions as a negative electrode.

Meanwhile, a first through hole P1 is formed in the first passivation layer 351a above the second ohmic electrode 340a to expose the second ohmic electrode 340a, and a second through hole P2 in communication with the first through hole P1 is formed in the second passivation layer 352a. The bonding pad layer 370a may be electrically connected to the second ohmic electrode 340a through the first through hole P1 and the second through hole P2.

The bonding pad layer 370a may basically include low melting point metals and noble metals such as gold (Au), silver (Ag), copper (Cu), and palladium (Pd), but the present invention is not limited thereto. In addition, the low melting point metals of the bonding pad layer 370a may be formed of metals such as In, Sn, Zn, and Pb alone or alloys including these metals.

Accordingly, in the epitaxial die 300a for a semiconductor light-emitting device according to the third embodiment of the present invention, the contact electrode 360a serving as a positive electrode and the first ohmic electrode 330a are interposed between the second passivation layer 352a and the light-emitting part 320a and thus are not exposed, and only the bonding pad layer 370a functioning as a negative electrode is exposed to the outside.

The second operation S32 is an operation of placing the epitaxial die 300a upside down on the first electrode pad 11aa, and electrically connecting the first electrode pad 11aa and the bonding pad layer 370a by bonding the first electrode pad 11aa and the bonding pad layer 370a through a bonding layer 12a. At this time, the placement and bonding of the epitaxial die 300a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 300a, (2) an epitaxial die 300a with an ultra-small size of less than 50 μm×50 μm, and (3) the epitaxial die 300a having a self-assembly structure, additional masking media (such as a photoresist, ceramics (like glass, quartz, and alumina), or an invar FMM) or processes may be employed before the placement and bonding of the epitaxial die 300a.

The third operation S33 is an operation of separating the final support substrate 310a of the epitaxial die 300a. At this time, in the third operation S33, the final support substrate 310a may be separated from the light-emitting part 320a, i.e., the second semiconductor region 322a, using an LLO technique to expose an upper surface of the second semiconductor region 322a. Here, the LLO technique is a technique of separating the final support substrate 310a from the epitaxially grown layers by irradiating a rear surface of the transparent final support substrate 310a with a UV laser beam having a uniform output and beam profile, and a single wavelength.

The fourth operation S34 is an operation of etching the other side of the light-emitting part 320a (that is, the side opposite to where the second ohmic electrode 340a is formed) to expose the first passivation layer 351a, and then etching the exposed first passivation layer 351a to expose the contact electrode 360a. At this time, a passivation layer may be additionally formed on the etched and exposed side surface of the light-emitting part 320a.

Meanwhile, in the fourth operation S34, a surface texture pattern of a predetermined shape or an irregular shape may be formed on an upper surface of the light-emitting part 320a, i.e., the upper surface of the second semiconductor region 322a, of the upside-down epitaxial die 300a to extract as much light generated in the active region 323a into the air as possible.

Meanwhile, before an electrical defect inspection is performed in the fifth operation S35, a mold part 14a surrounding the epitaxial die 300a may be formed in the fourth operation S34 such that the upper surface of the light-emitting part 320a, i.e., the upper surface of the second semiconductor region 322a, is exposed. At this time, the mold part 14a may be made of materials that enable LDS or LDI, allowing laser drilling in the sixth operation S36 to be described below. In addition, when the mold part 14a is not formed in the fourth operation S34, the contact electrode may be exposed after a photoresist (PR) is applied.

The fifth operation S35 is an operation of inspecting electrical defects of the epitaxial die 300a through the exposed contact electrode 360a, and repairing the semiconductor light-emitting device by replacing the corresponding epitaxial die 300a when the electrical defect inspection result indicates that the epitaxial die 300a is electrically defective. That is, in the present invention, electrical defects in the epitaxial die 300a can be detected and the defective epitaxial die 300a can be easily replaced before an upper wiring process is performed to form an extension electrode 13a.

The sixth operation S36 is an operation of forming the extension electrode 13a that electrically connects the second electrode pad 11ba and the contact electrode 360a. Meanwhile, when the mold part 14a is not formed in the fourth operation S34, the mold part 14a surrounding the epitaxial die 300a may be formed in the sixth operation S36, following the electrical defect inspection. That is, when the mold part 14a is formed after the electrical defect inspection in the fifth operation S35, there is an effect that the semiconductor light-emitting device is more easily repaired.

More specifically, in the sixth operation S36, laser drilling is used to etch the mold part 14a above the second electrode pad 11ba to form a through hole H above the second electrode pad 11ba, and when necessary, the first passivation layer 351a above the extension part 362a of the contact electrode 360a and the mold part 14a are etched to form a through hole H above the contact electrode 360a. Subsequently, in the sixth operation S36, the extension electrode 13a that electrically connects the second electrode pad 11ba and the exposed contact electrode 360a is formed, and the extension electrode 13a may have a shape formed to extend vertically from an upper portion of the second electrode pad 11ba to above the mold part 14a through the through hole H, then be bent and extend laterally toward the contact electrode 360a, and finally be bent vertically to extend toward and come into contact with the exposed contact electrode 360a.

The seventh operation S37 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S40) of manufacturing a semiconductor light-emitting device according to a fourth embodiment of the present invention will be described in detail.

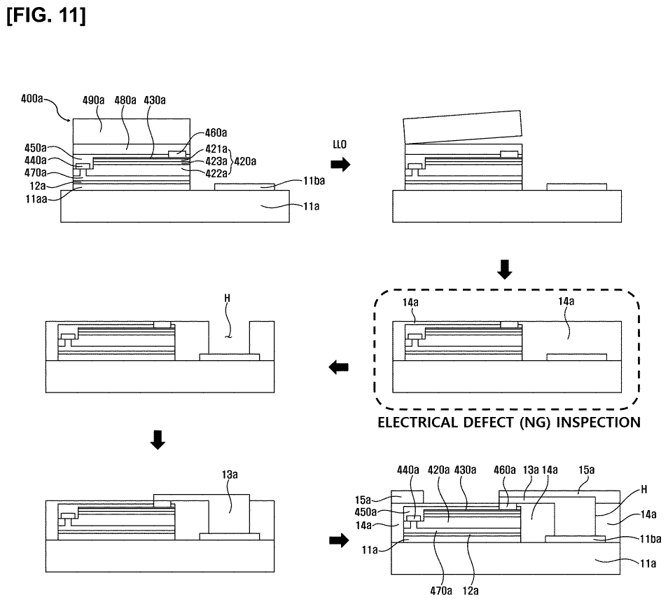

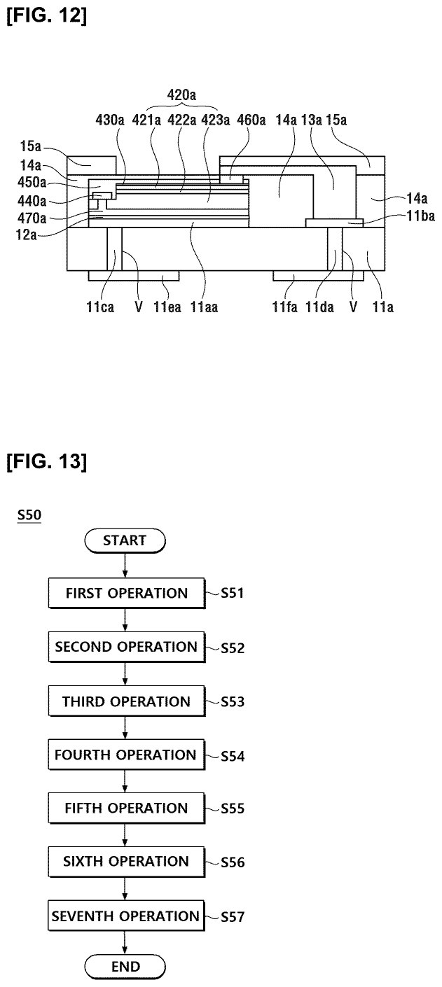

FIG. 10 is a flowchart illustrating a method of manufacturing a semiconductor light-emitting device that facilitates detection of electrical defects according to the fourth embodiment of the present invention, FIG. 11 illustrates a process of manufacturing the semiconductor light-emitting device that facilitates detection of electrical defects according to the fourth embodiment of the present invention, and FIG. 12 illustrates electrode posts formed in a substrate part of the semiconductor light-emitting device that facilitates detection of electrical defects according to the fourth embodiment of the present invention.

As shown in FIGS. 10 and 11, the method (S40) of manufacturing the semiconductor light-emitting device according to the fourth embodiment of the present invention includes a first operation S41, a second operation S42, a third operation S43, a fourth operation S44, a fifth operation S45, a sixth operation S46, and a seventh operation S47. However, it is of course possible to change the order of the processes shown in FIGS. 10 and 11.

The first operation S41 is an operation of preparing an epitaxial die 400a for a semiconductor light-emitting device according to the fourth embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 400a (e.g., the polarity of a bonding pad layer 470a).

Further, as shown in FIG. 12, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

In addition, the epitaxial die 400a for a semiconductor light-emitting device according to the fourth embodiment of the present invention includes a light-emitting part 420a that generates light, a first ohmic electrode 430a, a second ohmic electrode 440a, a passivation layer 450a, a contact electrode 460a that is not exposed to the outside, the bonding pad layer 470a that is exposed to the outside, a temporary bonding layer 480a, and a final support substrate 490a.

The light-emitting part 420a generates light, and details of a first semiconductor region 421a, a second semiconductor region 422a, and an active region 423a are the same as those of the above-described method (S10) of manufacturing the semiconductor light-emitting device that facilitates detection of electrical defects according to the first embodiment of the present invention, and thus redundant descriptions will be omitted (the structure of the epitaxial die 400a of the present invention is in a state in which an initial growth substrate is separated after the final support substrate 490a has been bonded).

Meanwhile, the light-emitting part 420a, which is epitaxially grown on the initial growth substrate in the order of the second semiconductor region 422a, the active region 423a, and the first semiconductor region 421a, has a structure in which the first semiconductor region 421a, the active region 423a, and the second semiconductor region 422a are stacked in that order on the final support substrate 490a when the first semiconductor region 421a is bonded to the final support substrate 490a through the temporary bonding layer 480a.

At this time, one side of the light-emitting part 420a formed on the initial growth substrate may have a shape etched to a predetermined depth (i.e., one side may have a mesa-etched shape), and here, the predetermined depth may refer to a depth up to the second semiconductor region 422a, but the present invention is not limited thereto. Meanwhile, the surface of the etched portion of the second semiconductor region 422a of the light-emitting part 420a has gallium (Ga) polarity.

The first ohmic electrode 430a is electrically connected to the first semiconductor region 421a of the light-emitting part 420a and is formed on the first semiconductor region 421a to cover and come into surface contact with an upper surface of the first semiconductor region 421a. At this time, the first semiconductor region 421a is electrically connected to the first ohmic electrode 430a through a p-ohmic contact.

The second ohmic electrode 440a is electrically connected to the second semiconductor region 422a of the light-emitting part 420a and is formed at the etched portion on one side of the second semiconductor region 422a.

The first ohmic electrode 430a and the second ohmic electrode 440a may each be formed of materials that essentially have high transparency and/or reflectance and excellent electrical conductivity, but the present invention is not limited thereto. The first ohmic electrode 430a may be made of materials including indium tin oxide (ITO), zinc oxide (ZnO), indium zinc oxide (IZO), indium gallium zinc oxide (IGZO), titanium nitride (TiN), Ni(O)—Au, Ni(O)—Ag, and the like. Meanwhile, the materials of the second ohmic electrode 440a may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, which may be used alone or in combination with the above-described metals.

At this time, as described above, the etched portion of the second semiconductor region 422a has a gallium (Ga) polar surface, and the gallium (Ga) polar surface is electrically connected to the second ohmic electrode 440a through an n-ohmic contact.

The passivation layer 450a covers the first ohmic electrode 430a from the etched portion on one side of the light-emitting part 420a via the second ohmic electrode 440a, and the other side (i.e., the side opposite to where the second ohmic electrode 440a is formed) of the light-emitting part 420a is partially etched to expose a portion of the first ohmic electrode 430a.

The passivation layer 450a may be implemented with electrically insulating materials, and may include, for example, a single layer or multiple layers including at least one material from among silicon oxide, silicon nitride, metallic oxides including Al₂O₃, and organic insulators.

The contact electrode 460a is electrically connected to the first ohmic electrode 430a and is formed on the first ohmic electrode 430a, which is exposed by partially etching the other side (i.e., the side opposite to where the second ohmic electrode 440a is formed) of the passivation layer 450a.

The materials of the contact electrode 460a are not limited as long as they have strong adhesion to the first ohmic electrode 430a, but may include Ti, TiN, Cr, CrN, V, VN, NiCr, Al, Rh, Pt, Ni, Pd, Ru, Cu, Ag, Au, and the like.

The temporary bonding layer 480a bonds the passivation layer 450a, in which the contact electrode 460a is exposed, to the final support substrate 490a, and is formed above the passivation layer 450a and the contact electrode 460a. Due to the shape of the temporary bonding layer 480a that encloses the contact electrode 460a, the contact electrode 460a is interposed between the temporary bonding layer 480a and the first ohmic electrode 430a and thus is not exposed.

The temporary bonding layer 480a may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 490a is bonded to the passivation layer 450a by the temporary bonding layer 480a to support the light-emitting part 420a, the first ohmic electrode 430a, the second ohmic electrode 440a, the passivation layer 450a, the contact electrode 460a, and the bonding pad layer 470a to be described below, and it is preferable that the final support substrate 490a be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 490a that meet these requirements include sapphire, which is used for the initial growth substrate, or glass that has been adjusted to have a difference in thermal expansion coefficient of 2 ppm or less from the initial growth substrate.

Meanwhile, in the present invention, the final support substrate 490a functions to support the light-emitting part 420a, the first ohmic electrode 430a, the second ohmic electrode 440a, the passivation layer 450a, the contact electrode 460a, and the bonding pad layer 470a to be described below after the epitaxial die 400a of the present invention is finally completed. At this time, it is preferable that an LLO sacrificial separation layer (not shown), which is a functional material that can be easily separated and removed by an LLO technique in the process of the third operation S43, which will be described below, be formed between the final support substrate 490a and the temporary bonding layer 480a. The above-described LLO sacrificial separation layer (not shown) may be made of materials such as ZnO, ITO, IZO, IGO, IGZO, InGaN, InGaON, GaON, TiN, SiO2, and SiNx.

The bonding pad layer 470a functions as a vertical chip die bonding pad, and is formed on a lower surface of the light-emitting part 420a to be electrically connected to the second ohmic electrode 440a. At this time, the bonding pad layer 470a is electrically connected to the second ohmic electrode 440a, is exposed to the outside, and functions as a negative electrode.

Meanwhile, a through hole P is formed below the light-emitting part 420a to expose the second ohmic electrode 440a, and the bonding pad layer 470a may be electrically connected to the second ohmic electrode 440a through the through hole P.

Meanwhile, it is preferable that the bonding pad layer 470a basically include three regions (not shown). A first region may include transparent electrically conductive materials (i.e., ITO, IZO, ZnO, IGZO, and TiN) with strong adhesion to the light-emitting part 420a. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 470a may be formed of metals such as In, Sn, Zn, and Pb alone or alloys including these metals.

Furthermore, although not shown in the drawing, before the bonding pad layer 470a is formed on the lower surface of the light-emitting part 420a, a surface texture pattern with a predetermined shape or an irregular shape may be formed on a lower surface of the second semiconductor region 422a to extract as much light generated in the active region 423a into the air as possible.

Accordingly, in the epitaxial die 400a for a semiconductor light-emitting device according to the fourth embodiment of the present invention, the contact electrode 460a serving as a positive electrode and the first ohmic electrode 430a are interposed between the temporary bonding layer 480a and the light-emitting part 420a and thus are not exposed, and only the bonding pad layer 470a functioning as a negative electrode is exposed to the outside.

The second operation S42 is an operation of placing the epitaxial die 400a on the first electrode pad 11aa, and electrically connecting the first electrode pad 11aa and the bonding pad layer 470a by bonding the first electrode pad 11aa and the bonding pad layer 470a through a bonding layer 12a. At this time, the placement and bonding of the epitaxial die 400a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 400a, (2) an epitaxial die 400a with an ultra-small size of less than 50 μm×50 μm, and (3) an epitaxial die 400a having a self-assembly structure, additional masking media (such as a photoresist, ceramics (like glass, quartz, and alumina), or an invar FMM) or processes may be employed before the placement and bonding of the epitaxial die 400a.

The third operation S43 is an operation of separating the final support substrate 490a of the epitaxial die 400a. At this time, in the third operation S43, the final support substrate 490a may be separated from the temporary bonding layer 480a using an LLO technique. Here, the LLO technique is a technique of separating the final support substrate 490a from the temporary bonding layer 480a by irradiating a rear surface of the transparent final support substrate 490a with a UV laser beam having a uniform output and beam profile, and a single wavelength.

The fourth operation S44 is an operation of etching and removing the temporary bonding layer 480a to expose the contact electrode 460a.

Meanwhile, in the fourth operation S44, a mold part 14a surrounding the epitaxial die 400a may be formed before electrical defect inspection is performed in the fifth operation S45. At this time, the mold part 14a may be made of materials that enable LDS or LDI, allowing laser drilling in the sixth operation S46 to be described below. In addition, when the mold part 14a is not formed in the fourth operation S44, the contact electrode may be exposed after a photoresist (PR) is applied.

The fifth operation S45 is an operation of inspecting electrical defects of the epitaxial die 400a through the exposed contact electrode 460a, and repairing the semiconductor light-emitting device by replacing the corresponding epitaxial die 400a when the electrical defect inspection result indicates that the epitaxial die 400a is electrically defective. That is, in the present invention, electrical defects in the epitaxial die 400a can be detected and the defective epitaxial die 400a can be easily replaced before an upper wiring process is performed to form an extension electrode 13a.

The sixth operation S46 is an operation of forming the extension electrode 13a that electrically connects the second electrode pad 11ba and the contact electrode 460a. Meanwhile, when the mold part 14a is not formed in the fourth operation S44, the mold part 14a surrounding the epitaxial die 400a may be formed in the sixth operation S46, following the electrical defect inspection. That is, when the mold part 14a is formed after the electrical defect inspection in the fifth operation S45, there is an effect that the semiconductor light-emitting device is more easily repaired.

More specifically, in the sixth operation S46, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 460a, thereby electrically connecting the contact electrode 460a and the second electrode pad 11ba.

The seventh operation S47 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S50) of manufacturing a semiconductor light-emitting device according to a fifth embodiment of the present invention will be described in detail.

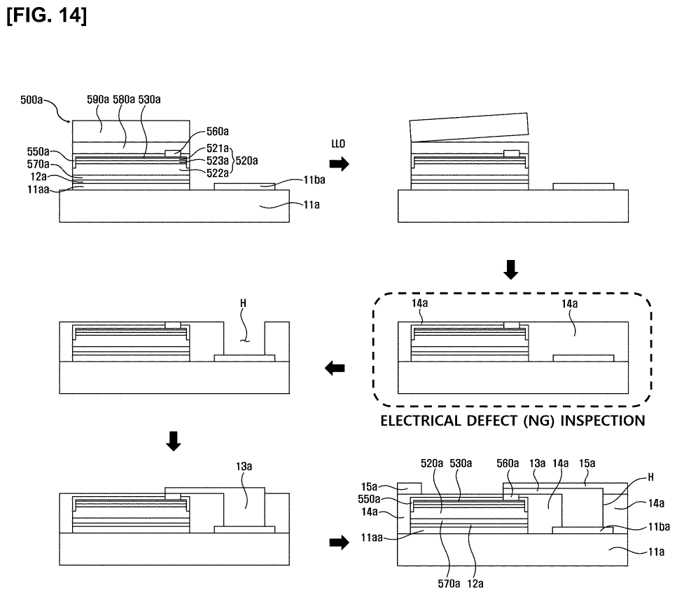

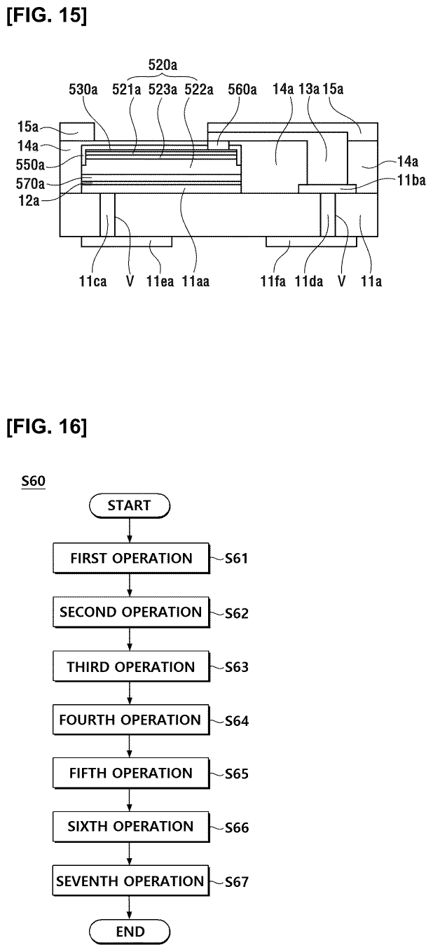

FIG. 13 is a flowchart illustrating a method of manufacturing a semiconductor light-emitting device that facilitates detection of electrical defects according to the fifth embodiment of the present invention, FIG. 14 illustrates a process of manufacturing the semiconductor light-emitting device that facilitates detection of electrical defects according to the fifth embodiment of the present invention, and FIG. 15 illustrates electrode posts formed in a substrate part of the semiconductor light-emitting device that facilitates detection of electrical defects according to the fifth embodiment of the present invention.

As shown in FIGS. 13 and 14, the method (S50) of manufacturing the semiconductor light-emitting device according to the fifth embodiment of the present invention includes a first operation S51, a second operation S52, a third operation S53, a fourth operation S54, a fifth operation S55, a sixth operation S56, and a seventh operation S57. However, it is of course possible to change the order of the processes shown in FIGS. 13 and 14.

The first operation S51 is an operation of preparing an epitaxial die 500a for a semiconductor light-emitting device according to the fifth embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 500a (e.g., the polarity of a bonding pad layer 570a).

Further, as shown in FIG. 15, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

Further, the epitaxial die 500a for a semiconductor light-emitting device according to the fifth embodiment of the present invention includes a light-emitting part 520a that generates light, a first ohmic electrode 530a, a passivation layer 550a, a contact electrode 560a that is not exposed to the outside, the bonding pad layer 570a that is exposed to the outside, a temporary bonding layer 580a, and a final support substrate 590a.

The light-emitting part 520a generates light, and details of a first semiconductor region 521a, a second semiconductor region 522a, and an active region 523a are the same as those of the above-described method (S10) of manufacturing the semiconductor light-emitting device that facilitates detection of electrical defects according to the first embodiment of the present invention, and thus redundant descriptions will be omitted (the structure of the epitaxial die 500a of the present invention is in a state in which an initial growth substrate is separated after the final support substrate 590a has been bonded).

Meanwhile, the light-emitting part 520a, which is epitaxially grown on the initial growth substrate in the order of the second semiconductor region 522a, the active region 523a, and the first semiconductor region 521a, has a structure in which the first semiconductor region 521a, the active region 523a, and the second semiconductor region 522a are stacked in that order on the final support substrate 590a when the first semiconductor region 521a is bonded to the final support substrate 590a through the temporary bonding layer 580a.

At this time, both sides of the light-emitting part 520a formed on the initial growth substrate may have a shape etched to a predetermined depth, and here, the predetermined depth may refer to a depth up to the second semiconductor region 522a, but the present invention is not limited thereto.

The first ohmic electrode 530a is electrically connected to the first semiconductor region 521a of the light-emitting part 520a and is formed on the first semiconductor region 521a to cover and come into surface contact with an upper surface of the first semiconductor region 521a. At this time, the first semiconductor region 521a is electrically connected to the first ohmic electrode 530a through a p-ohmic contact.

This first ohmic electrode 530a may be basically formed of a material with high transparency and excellent electrical conductivity, but the present invention is not limited thereto. The first ohmic electrode 530a may be made of optically transparent materials such as indium tin oxide (ITO), zinc oxide (ZnO), indium zinc oxide (IZO), indium gallium zinc oxide (IGZO), titanium nitride (TiN), Ni(O)—Au, Ni(O)—Ag, and the like.

The passivation layer 550a covers the first ohmic electrode 530a from the etched portions on both sides of the light-emitting part 520a, and is partially etched to expose a portion of the first ohmic electrode 530a.

The passivation layer 550a may be implemented with electrically insulating materials, and may include, for example, a single layer or multiple layers including at least one material from among silicon oxide, silicon nitride, metallic oxides including Al₂O₃, and organic insulators.

The contact electrode 560a is electrically connected to the first ohmic electrode 530a and is formed on the first ohmic electrode 530a exposed by etching a portion of the passivation layer 550a.

The materials of the contact electrode 560a are not limited as long as they have strong adhesion to the first ohmic electrode 530a, but may include Ti, TiN, Cr, CrN, V, VN, NiCr, Al, Rh, Pt, Ni, Pd, Ru, Cu, Ag, Au, and the like.

The temporary bonding layer 580a bonds the passivation layer 550a, in which the contact electrode 560a is exposed, to the final support substrate 590a, and is formed above the passivation layer 550a and the contact electrode 560a. Due to the shape of the temporary bonding layer 580a that encloses the contact electrode 560a, the contact electrode 560a is interposed between the temporary bonding layer 580a and the first ohmic electrode 530a and thus is not exposed.

The temporary bonding layer 580a may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 590a is bonded to the passivation layer 550a by the temporary bonding layer 580a to support the light-emitting part 520a, the first ohmic electrode 530a, the passivation layer 550a, the contact electrode 560a, and the bonding pad layer 570a to be described below, and it is preferable that the final support substrate 590a be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 590a that meet these requirements include sapphire, which is used for the initial growth substrate, or glass that has been adjusted to have a difference in thermal expansion coefficient of 2 ppm or less from the initial growth substrate.

Meanwhile, in the present invention, the final support substrate 590a functions as a final support substrate that supports the light-emitting part 520a, the first ohmic electrode 530a, the passivation layer 550a, the contact electrode 560a, and the bonding pad layer 570a to be described below after the epitaxial die 500a of the present invention is finally completed. At this time, it is preferable that an LLO sacrificial separation layer (not shown), which is a functional material that can be easily separated and removed by an LLO technique in the process of the third operation S53, which will be described below, be formed between the final support substrate 590a and the temporary bonding layer 580a. The above-described LLO sacrificial separation layer (not shown) may be made of materials such as ZnO, ITO, IZO, IGO, IGZO, InGaN, InGaON, GaON, TiN, SiO2, and SiNx.

The bonding pad layer 570a functions as a vertical chip die bonding pad, and is formed on a lower surface of the light-emitting part 520a to be electrically connected to the light-emitting part 520a. At this time, the lower surface of the light-emitting part 520a has a nitrogen (N) polar surface, and the bonding pad layer 570a is electrically connected to the nitrogen (N) polar surface through an n-ohmic contact, is exposed to the outside, and functions as a negative electrode as well as an active reflector.

Meanwhile, it is preferable that the bonding pad layer 570a basically include three regions (not shown). A first region may include transparent electrically conductive materials (i.e., ITO, IZO, ZnO, IGZO, and TiN) with strong adhesion to the light-emitting part 520a. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 570a may be formed of metals such as In, Sn, Zn, and Pb alone or alloys including these metals.

Furthermore, although not shown in the drawing, before the bonding pad layer 570a is formed on the lower surface of the light-emitting part 520a, a surface texture pattern with a predetermined shape or an irregular shape may be formed on a lower surface of the second semiconductor region 522a to extract as much light generated in the active region 523a into the air as possible.

Accordingly, in the epitaxial die 500a for a semiconductor light-emitting device according to the fifth embodiment of the present invention, the contact electrode 560a serving as a positive electrode and the first ohmic electrode 530a are interposed between the temporary bonding layer 580a and the light-emitting part 520a and thus are not exposed, and only the bonding pad layer 570a functioning as a negative electrode is exposed to the outside.

The second operation S52 is an operation of placing the epitaxial die 500a on the first electrode pad 11aa, and electrically connecting the first electrode pad 11aa and the bonding pad layer 570a by bonding the first electrode pad 11aa and the bonding pad layer 570a through a bonding layer 12a. At this time, the placement and bonding of the epitaxial die 500a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 500a, (2) an epitaxial die 500a with an ultra-small size of less than 50 μm×50 μm, and (3) an epitaxial die 500a having a self-assembly structure, additional masking media (such as a photoresist, ceramics (like glass, quartz, and alumina), or an invar FMM) or processes may be employed before the placement and bonding of the epitaxial die 500a.

The third operation S53 is an operation of separating the final support substrate 590a of the epitaxial die 500a. At this time, in the third operation S53, the final support substrate 590a may be separated from the temporary bonding layer 580a using an LLO technique. Here, the LLO technique is a technique of separating the final support substrate 590a from the temporary bonding layer 580a by emitting a UV laser beam having a uniform output and beam profile, and a single wavelength onto a rear surface of the transparent final support substrate 590a.

The fourth operation S54 is an operation of etching and removing the temporary bonding layer 580a to expose the contact electrode 560a.

Meanwhile, in the fourth operation S54, a mold part 14a surrounding the epitaxial die 500a may be formed before electrical defect inspection is performed in the fifth operation S55. At this time, the mold part 14a may be made of materials that enable LDS or LDI, allowing laser drilling in the sixth operation S56 to be described below. In addition, when the mold part 14a is not formed in the fourth operation S54, the contact electrode may be exposed after a photoresist (PR) is applied.

The fifth operation S55 is an operation of inspecting electrical defects of the epitaxial die 500a through the exposed contact electrode 560a, and repairing the semiconductor light-emitting device by replacing the corresponding epitaxial die 500a when the electrical defect inspection result indicates that the epitaxial die 500a is electrically defective. That is, in the present invention, electrical defects in the epitaxial die 500a can be detected and the defective epitaxial die 500a can be easily replaced before an upper wiring process is performed to form an extension electrode 13a.

The sixth operation S56 is an operation of forming the extension electrode 13a that electrically connects the second electrode pad 11ba and the contact electrode 560a. Meanwhile, when the mold part 14a is not formed in the fourth operation S54, the mold part 14a surrounding the epitaxial die 500a may be formed in the sixth operation S56, following the electrical defect inspection. That is, when the mold part 14a is formed after the electrical defect inspection in the fifth operation S55, there is an effect that the semiconductor light-emitting device is more easily repaired.

More specifically, in the sixth operation S56, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 560a, thereby electrically connecting the contact electrode 560a and the second electrode pad 11ba.

The seventh operation S57 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S60) of manufacturing a semiconductor light-emitting device according to a sixth embodiment of the present invention will be described in detail.

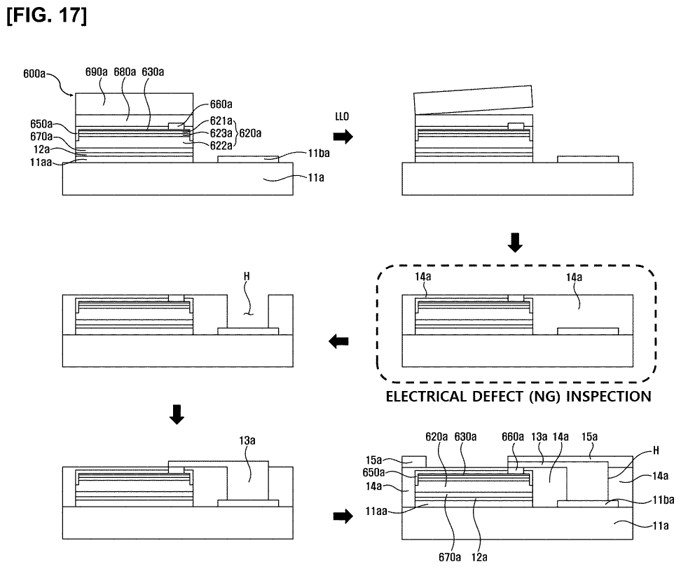

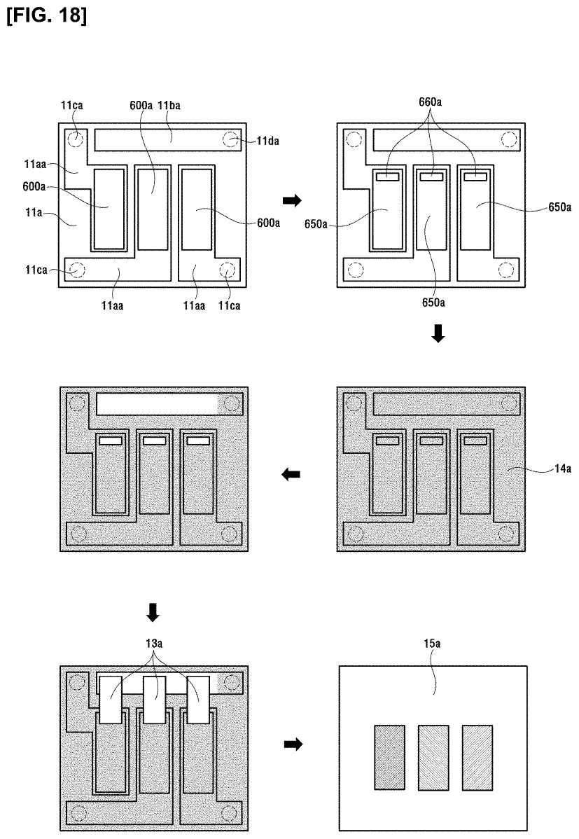

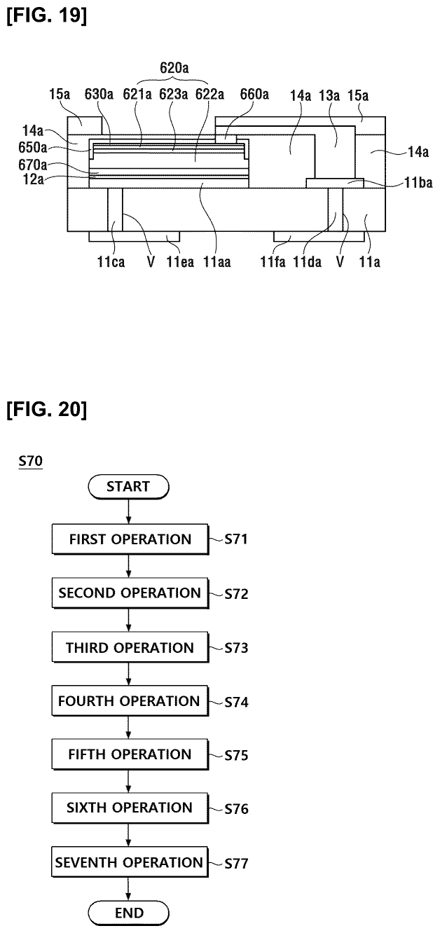

FIG. 16 is a flowchart illustrating a method of manufacturing a semiconductor light-emitting device that facilitates detection of electrical defects according to the sixth embodiment of the present invention, FIGS. 17 and 18 illustrate a process of manufacturing the semiconductor light-emitting device that facilitates detection of electrical defects according to the sixth embodiment of the present invention, and FIG. 19 illustrates electrode posts formed in a substrate part of the semiconductor light-emitting device that facilitates detection of electrical defects according to the sixth embodiment of the present invention.

As shown in FIGS. 16 to 18, the method (S60) of manufacturing the semiconductor light-emitting device according to the sixth embodiment of the present invention includes a first operation S61, a second operation S62, a third operation S63, a fourth operation S64, a fifth operation S65, a sixth operation S66, and a seventh operation S67. However, it is of course possible to change the order of the processes shown in FIGS. 16 to 18.

The first operation S61 is an operation of preparing an epitaxial die 600a for a semiconductor light-emitting device according to the sixth embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 600a (e.g., the polarity of a bonding pad layer 670a).

Further, as shown in FIG. 19, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

In addition, as shown in FIG. 18, the first electrode post 11ca and the second electrode post 11da may each be formed in the shape of a column (a post) in the via hole V that passes through the substrate part 11a, using copper (Cu) plating (or by inserting a nickel (Ni) wire), and in this case, the via hole V may be formed at each of four corner portions of the substrate part 11a to enhance a bonding strength of the substrate part 11a through a plurality of electrode posts 11ca and 11da. For example, when the epitaxial die is transferred (placed) onto the substrate part 11a, three first electrode posts 11ca, which are individual electrodes, may be formed in the via holes V at the corner portions of the substrate part 11a, while one second electrode post 11da, which is a common electrode, may be formed in the via hole V at the remaining corner of the substrate part 11a. Subsequently, the first electrode post 11ca may be electrically connected to the bonding pad layer 670a of the epitaxial die, and the second electrode post 11da may be electrically connected to a contact electrode 660a of the epitaxial die through an extension electrode 13a. Furthermore, it is of course possible to apply the above-described structure to the semiconductor light-emitting devices of the first to ninth embodiments of the present invention.

Further, the epitaxial die 600a for a semiconductor light-emitting device according to the sixth embodiment of the present invention includes a light-emitting part 620a that generates light, a first ohmic electrode 630a, a passivation layer 650a, the contact electrode 660a that is not exposed to the outside, the bonding pad layer 670a that is exposed to the outside, a temporary bonding layer 680a, and a final support substrate 690a.

The light-emitting part 620a generates light, and in the present invention, in order to emit red light, binary, ternary, and quaternary compounds of Group III (Al, Ga, and In) phosphide semiconductors, such as indium phosphide (InP), indium gallium phosphide (InGaP), gallium phosphide (GaP), aluminum indium phosphide (AlInP), aluminum gallium phosphide (AlGaP), aluminum phosphide (AIP), and aluminum gallium indium phosphide (AlGaInP), are placed in appropriate positions and sequences on an initial growth substrate and epitaxially grown (in the structure of the epitaxial die 600a of the present invention, the initial growth substrate is separated after the final support substrate 690a is bonded).

In particular, in order to emit red light, a high-quality Group III phosphide semiconductor with a high indium (In) composition, such as indium gallium phosphide (InGaP), should preferentially be formed on top of Group III phosphide semiconductors composed of gallium phosphide (GaP), aluminum indium phosphide (AlInP), aluminum gallium phosphide (AlGaP), aluminum phosphide (AIP), and aluminum gallium indium phosphide (AlGaInP), but the present invention is not limited thereto.

More specifically, the light-emitting part 620a includes a first semiconductor region 621a (e.g., a p-type semiconductor region), an active region 623a (e.g., MQWs), and a second semiconductor region 622a (e.g., an n-type semiconductor region), and the light-emitting part 620a may have a structure in which the second semiconductor region 622a, the active region 623a, and the first semiconductor region 621a are epitaxially grown in that order on the initial growth substrate, and ultimately, may have an overall thickness typically ranging from about 5.0 to 8.0 μm, including multiple layers of group III phosphides, but the present invention is not limited thereto.

Each of the first semiconductor region 621a, the active region 623a, and the second semiconductor region 622a may be formed as either a single layer or multiple layers, and although not shown in the drawing, necessary layers, such as buffer regions, may be added before the light-emitting part 620a is epitaxially grown on the gallium arsenide (GaAs) initial growth substrate to ensure the high quality of the epitaxially grown light-emitting part 620a. For example, the buffer regions may include a nucleation layer and a compliant layer composed of an un-doped semiconductor region to relieve stress and improve thin-film quality and typically have a thickness of about 4.0 μm. In addition, since the initial growth substrate must be removed using a CLO technique, it is preferable to grow an etching-stop layer (ESL) composed of gallium indium phosphide (GaInP) as a single-crystal thin film with a thickness of about 200 nm directly on the GaAs initial growth substrate before the doped first semiconductor region 621a or second semiconductor region 622a is deposited.

The second semiconductor region 622a has a second conductivity type (n-type), and is formed on the initial growth substrate. The second semiconductor region 622a is primarily composed of gallium arsenide (GaAs) and aluminum gallium indium phosphide (AlGaInP) semiconductors, and may have a thickness ranging from 2.0 to 3.5 μm.

The active region 623a generates light, i.e., red light, by using the recombination of electrons and holes, and is formed on the second semiconductor region 622a. The active region 623a is composed of multiple layers of semiconductors, including primarily gallium indium phosphide (GaInP) and aluminum gallium indium phosphide (AlGaInP), and may have a thickness of several tens of nanometers (nm).

The first semiconductor region 621a has a first conductivity type (p-type), and is formed on the active region 623a. The first semiconductor region 621a is composed of multiple layers of semiconductors, including primarily aluminum indium phosphide (AlInP), aluminum gallium indium phosphide (AlGaInP), and gallium phosphide (GaP), and may have a thickness ranging from several tens of nanometers (nm) to several micrometers (μm).

That is, the active region 623a is interposed between the first semiconductor region 621a and the second semiconductor region 622a, and light is generated when holes in the first semiconductor region 621a, which is a p-type semiconductor region, and electrons in the second semiconductor region 622a, which is an n-type semiconductor region, recombine in the active region 623a.

Meanwhile, the light-emitting part 620a, which is epitaxially grown on the initial growth substrate in the order of the second semiconductor region 622a, the active region 623a, and the first semiconductor region 621a, has a structure in which the first semiconductor region 621a, the active region 623a, and the second semiconductor region 622a are stacked in that order on the final support substrate 690a when the first semiconductor region 621a is bonded to the sapphire final support substrate 690a through the temporary bonding layer 680a.

At this time, both sides of the light-emitting part 620a formed on the initial growth substrate may have a shape etched to a predetermined depth, and here, the predetermined depth may refer to a depth up to the second semiconductor region 622a, but the present invention is not limited thereto.

The first ohmic electrode 630a is electrically connected to the first semiconductor region 621a of the light-emitting part 620a and is formed on the first semiconductor region 621a to cover and come into surface contact with an upper surface of the first semiconductor region 621a. At this time, the first semiconductor region 621a, which is a p-type semiconductor region, is electrically connected to the first ohmic electrode 630a through a p-ohmic contact.

This first ohmic electrode 630a may be basically formed of a material with high transparency and excellent electrical conductivity, but the present invention is not limited thereto. The first ohmic electrode 630a may be made of optically transparent materials such as indium tin oxide (ITO), zinc oxide (ZnO), indium zinc oxide (IZO), indium gallium zinc oxide (IGZO), titanium nitride (TiN), Ni(O)—Au, Ni(O)—AuBe, Ni(O)—Ag, and the like.

The passivation layer 650a covers the first ohmic electrode 630a from the etched portions on both sides of the light-emitting part 620a, and a portion of the first ohmic electrode 630a is exposed as a portion of the passivation layer 650a is etched and is opened.

The passivation layer 650a may be implemented with electrically insulating materials, and may include, for example, a single layer or multiple layers including at least one material from among silicon oxide, silicon nitride, metallic oxides including Al₂O₃, and organic insulators.

The contact electrode 660a is electrically connected to the first ohmic electrode 630a and is formed on the first ohmic electrode 630a exposed by opening a portion of the passivation layer 650a.

The materials of the contact electrode 660a are not limited as long as they have strong adhesion to the first ohmic electrode 630a, but may include Ti, TiN, Cr, CrN, V, VN, NiCr, Al, Rh, Pt, Ni, Pd, Ru, Cu, Ag, Au, AuBe, and the like.

The temporary bonding layer 680a bonds the passivation layer 650a, in which the contact electrode 660a is exposed, to the final support substrate 690a, and is formed above the passivation layer 650a and the contact electrode 660a. Due to the shape of the temporary bonding layer 680a that encloses the contact electrode 660a, the contact electrode 660a is interposed between the temporary bonding layer 680a and the first ohmic electrode 630a and thus is not exposed.

The temporary bonding layer 680a may include materials such as benzocyclobutene (BCB), SU-8 polymer, flowable oxides (FOX) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 690a is bonded to the passivation layer 650a by the temporary bonding layer 680a to support the light-emitting part 620a, the first ohmic electrode 630a, the passivation layer 650a, the contact electrode 660a, and the bonding pad layer 670a to be described below, and it is preferable that the final support substrate 690a be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 690a that meet these criteria may include sapphire, or glass that has been adjusted to have a difference in thermal expansion coefficient of 2 ppm or less from the initial growth substrate.

Meanwhile, in the present invention, the final support substrate 690a functions to support the light-emitting part 620a, the first ohmic electrode 630a, the passivation layer 650a, the contact electrode 660a, and the bonding pad layer 670a to be described below after the epitaxial die 600a of the present invention is finally completed. At this time, it is preferable that an LLO sacrificial separation layer (not shown), which is a functional material that can be easily separated and removed by an LLO technique in the process of the third operation S63, be formed between the final support substrate 690a and the temporary bonding layer 680a. The above-described LLO sacrificial separation layer (not shown) may be made of materials such as ZnO, ITO, IZO, IGO, IGZO, InGaN, InGaON, GaON, TIN, SiO2, and SiNx.

The bonding pad layer 670a functions as a vertical chip die bonding pad, and is formed to come into contact with a lower surface of the light-emitting part 620a to be electrically connected to the light-emitting part 620a. At this time, the bonding pad layer 670a is electrically connected to a lower surface of the second semiconductor region 622a, which is an n-type semiconductor region, through an n-ohmic contact, is exposed to the outside, and functions as a negative electrode while also serving as an active reflector.

It is preferable that the bonding pad layer 670a basically include three regions (not shown). A first region may include transparent electrically conductive materials (i.e., ITO, IZO, ZnO, IGZO, TiN, and (O)—AuGe) with strong adhesion to the light-emitting part 620a. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 670a may be formed of metals such as In, Sn, Zn, and Pb alone or alloys including these metals.

Furthermore, although not shown in the drawing, before the bonding pad layer 670a is formed on the lower surface of the light-emitting part 620a, a surface texture pattern with a predetermined shape or an irregular shape may be formed on the lower surface of the second semiconductor region 622a to extract as much light generated in the active region 623a into the air as possible.

Accordingly, in the epitaxial die 600a for a semiconductor light-emitting device according to the sixth embodiment of the present invention, the contact electrode 660a serving as a positive electrode and the first ohmic electrode 630a are interposed between the temporary bonding layer 680a and the light-emitting part 620a and thus are not exposed, and only the bonding pad layer 670a functioning as a negative electrode is exposed to the outside.

The second operation S62 is an operation of placing the epitaxial die 600a on the first electrode pad 11aa, and electrically connecting the first electrode pad 11aa and the bonding pad layer 670a by bonding the first electrode pad 11aa and the bonding pad layer 670a through a bonding layer 12a. At this time, the placement and bonding of the epitaxial die 600a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 600a, (2) an epitaxial die 600a with an ultra-small size of less than 50 μm×50 μm, and (3) an epitaxial die 600a having a self-assembly structure, additional masking media (such as a photoresist, ceramics (like glass, quartz, and alumina), or an invar FMM) or processes may be employed before the placement and bonding of the epitaxial die 600a.

The third operation S63 is an operation of separating the final support substrate 690a of the epitaxial die 600a. At this time, in the third operation S63, the final support substrate 690a may be separated from the temporary bonding layer 680a using an LLO technique. Here, the LLO technique is a technique of separating the final support substrate 690a from the temporary bonding layer 680a by emitting a UV laser beam having a uniform output and beam profile, and a single wavelength onto a rear surface of the transparent final support substrate 690a.

The fourth operation S64 is an operation of etching and removing the temporary bonding layer 680a to expose the contact electrode 660a.

Meanwhile, in the fourth operation S64, a mold part 14a surrounding the epitaxial die 600a may be formed before electrical defect inspection is performed in the fifth operation S65. At this time, the mold part 14a may be made of materials that enable LDS or LDI, allowing laser drilling in the sixth operation S66 to be described below. In addition, when the mold part 14a is not formed in the fourth operation S64, the contact electrode may be exposed after a photoresist (PR) is applied.

The fifth operation S65 is an operation of inspecting electrical defects of the epitaxial die 600a through the exposed contact electrode 660a, and repairing the semiconductor light-emitting device by replacing the corresponding epitaxial die 600a when the electrical defect inspection result indicates that the epitaxial die 600a is electrically defective. That is, in the present invention, electrical defects in the epitaxial die 600a can be detected and the defective epitaxial die 600a can be easily replaced before an upper wiring process is performed to form the extension electrode 13a.

The sixth operation S66 is an operation of forming the extension electrode 13a that electrically connects the second electrode pad 11ba and the contact electrode 660a. Meanwhile, when the mold part 14a is not formed in the fourth operation S64, the mold part 14a surrounding the epitaxial die 600a may be formed in the sixth operation S66, following the electrical defect inspection. That is, when the mold part 14a is formed after the electrical defect inspection in the fifth operation S65, there is an effect that the semiconductor light-emitting device is more easily repaired.

More specifically, in the sixth operation S66, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 660a, thereby electrically connecting the contact electrode 660a and the second electrode pad 11ba.

The seventh operation S67 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S70) of manufacturing a semiconductor light-emitting device according to a seventh embodiment of the present invention will be described in detail.

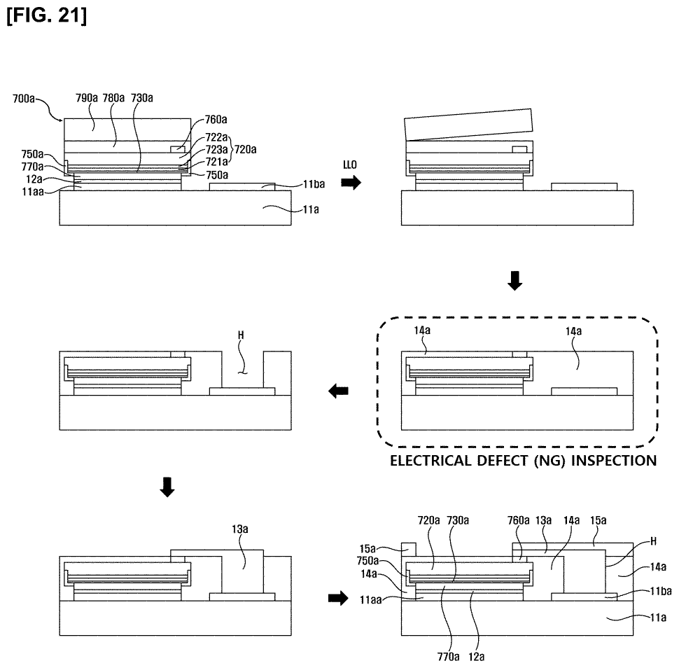

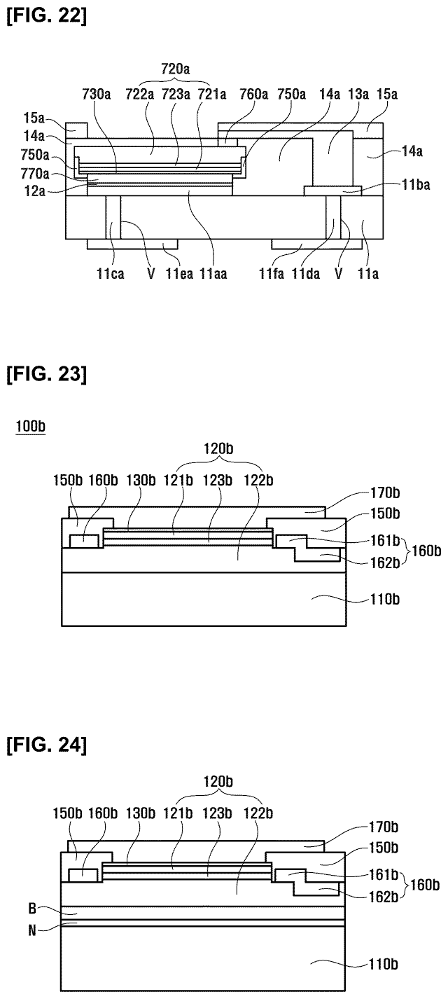

FIG. 20 is a flowchart illustrating a method of manufacturing a semiconductor light-emitting device that facilitates detection of electrical defects according to the seventh embodiment of the present invention, FIG. 21 illustrates a process of manufacturing the semiconductor light-emitting device that facilitates detection of electrical defects according to the seventh embodiment of the present invention, and FIG. 22 illustrates electrode posts formed in a substrate part of the semiconductor light-emitting device that facilitates detection of electrical defects according to the seventh embodiment of the present invention.

As shown in FIGS. 20 and 21, the method (S70) of manufacturing the semiconductor light-emitting device according to the seventh embodiment of the present invention includes a first operation S71, a second operation S72, a third operation S73, a fourth operation S74, a fifth operation S75, a sixth operation S76, and a seventh operation S77. However, it is of course possible to change the order of the processes shown in FIGS. 20 and 21.

The first operation S71 is an operation of preparing an epitaxial die 700a for a semiconductor light-emitting device according to the seventh embodiment of the present invention, and a substrate part 11a on which a first electrode pad 11aa and a second electrode pad 11ba are formed. The substrate part 11a may be a semiconductor wafer, a PCB, TFT glass, an interposer, or the like, but the present invention is not limited thereto. Meanwhile, when the first electrode pad 11aa is an individual negative electrode, the second electrode pad 11ba may be a common positive electrode, and when the first electrode pad 11aa is an individual positive electrode, the second electrode pad 11ba may be a common negative electrode, which may vary depending on the characteristics of the epitaxial die 700a (e.g., the polarity of a bonding pad layer 770a).

Further, as shown in FIG. 22, when the substrate part 11a has a first electrode post 11ca and a second electrode post 11da formed through via holes V formed therein, a first upper electrode pad 11aa electrically connected to the first electrode post 11ca at an upper portion of the first electrode post 11ca, a second upper electrode pad 11ba electrically connected to the second electrode post 11da at an upper portion of the second electrode post 11da, a first lower electrode pad 11ea electrically connected to the first electrode post 11ca at a lower portion of the first electrode post 11ca, and a second lower electrode pad 11fa electrically connected to the second electrode post 11da at a lower portion of the second electrode post 11da may be formed.

Further, the epitaxial die 700a for a semiconductor light-emitting device according to the seventh embodiment of the present invention includes a light-emitting part 720a that generates light, a first ohmic electrode 730a, a passivation layer 750a, a contact electrode 760a that is not exposed to the outside, the bonding pad layer 770a that is exposed to the outside, a temporary bonding layer 780a, and a final support substrate 790a.

The light-emitting part 720a generates light, and details of a first semiconductor region 721a, a second semiconductor region 722a, and an active region 723a are the same as those of the above-described method (S60) of manufacturing the semiconductor light-emitting device that facilitates detection of electrical defects according to the sixth embodiment of the present invention, and thus redundant descriptions will be omitted (the structure of the epitaxial die 700a of the present invention is in a state in which after the intermediate temporary substrate is bonded and the initial growth substrate is separated, the final support substrate 790a is bonded and the intermediate temporary substrate is separated).

Meanwhile, the light-emitting part 720a, which is epitaxially grown on the initial growth substrate in the order of the second semiconductor region 722a, the active region 723a, and the first semiconductor region 721a, subsequently has a structure in which, after a sapphire intermediate temporary substrate is bonded on the first semiconductor region 721a through the temporary bonding layer 780a and the initial growth substrate is separated, the sapphire final support substrate 790a is bonded to a lower surface of the second semiconductor region 722a through another temporary bonding layer 780a, resulting in the second semiconductor region 722a, the active region 723a, and the first semiconductor region 721a being sequentially stacked on the final support substrate 790a.

At this time, both sides of the light-emitting part 720a formed on the initial growth substrate may have a shape etched to a predetermined depth, and here, the predetermined depth may refer to a depth up to the second semiconductor region 722a, but the present invention is not limited thereto.

The first ohmic electrode 730a is electrically connected to the first semiconductor region 721a of the light-emitting part 720a and is formed on the first semiconductor region 721a to cover and come into surface contact with an upper surface of the first semiconductor region 721a. At this time, the first semiconductor region 721a, which is a p-type semiconductor region, is electrically connected to the first ohmic electrode 730a through a p-ohmic contact.

The first ohmic electrode 730a may basically be formed solely of a material with high reflectance and excellent electrical conductivity, Furthermore, the first ohmic electrode 730a may also be formed in combination with a material that has high transparency, but the present invention is not limited thereto. The materials for the first ohmic electrode 730a with high reflectance described above may include metals such as Ag, Al, Rh, Pt, Ni, Pd, Ru, Cu, Au, AuBe, AgBe, and AlBe, and the materials for the first ohmic electrode 730a with high transparency described above may include indium tin oxide (ITO), zinc oxide (ZnO), indium zinc oxide (IZO), indium gallium zinc oxide (IGZO), titanium nitride (TiN), Ni(O)—Au, Ni(O)—AuBe, Ni(O)—Ag, and the like.

The passivation layer 750a covers the first ohmic electrode 730a from the etched portions on both sides of the light-emitting part 720a, and a portion of the first ohmic electrode 730a is exposed as a portion of the passivation layer 750a is etched and opened.

The passivation layer 750a may be implemented with electrically insulating materials, and may include, for example, a single layer or multiple layers including at least one material from among silicon oxide, silicon nitride, metallic oxides including Al₂O₃, and organic insulators.

The bonding pad layer 770a functions as a vertical chip die bonding pad and is formed on the first ohmic electrode 730a, which is exposed by the partial opening of the passivation layer 750a. The bonding pad layer 770a is electrically connected to the first ohmic electrode 730a, is exposed to the outside, and functions as a positive electrode.

The bonding pad layer 770a may basically include low melting point metals and noble metals such as gold (Au), silver (Ag), copper (Cu), and palladium (Pd), but the present invention is not limited thereto. In addition, the above-described low melting point metals may be formed of metals such as In, Sn, Zn, and Pb alone or alloys including these metals.

The contact electrode 760a is formed to come into contact with a lower surface of the light-emitting part 720a to be electrically connected to the light-emitting part 720a, and in this case, the contact electrode 760a is electrically connected to a lower surface of the second semiconductor region 722a, which is an n-type semiconductor region, through an n-ohmic contact, and functions as a negative electrode.

The materials for the contact electrode 760a are not limited as long as they are compatible with the lower surface of the second semiconductor region 722a, which is an n-type semiconductor region, and may include Ti, TiN, Cr, CrN, V, VN, NiCr, Al, Rh, Pt, Ni, Pd, Ru, Cu, Ag, Au, NiO, AuGe, and the like.

Meanwhile, although not shown in the drawing, before the final support substrate 790a is bonded to the lower surface of the light-emitting part 720a, a surface texture pattern with a predetermined shape or an irregular shape may be formed on the lower surface of the second semiconductor region 722a to extract as much light generated in the active region 723a into the air as possible.

The temporary bonding layer 780a bonds the lower surface of the light-emitting part 720a, in which the contact electrode 760a is formed, to the final support substrate 790a, and is formed on the lower surface of the light-emitting part 720a to cover the contact electrode 760a. Due to the shape of the temporary bonding layer 780a that encloses the contact electrode 760a, the contact electrode 760a is interposed between the temporary bonding layer 780a and the light-emitting part 720a and thus is not exposed.

The temporary bonding layer 780a may include materials such as benzocyclobutene (BCB), SU-8 polymer, flowable oxides (FOX) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 790a is bonded to the passivation layer 750a by the temporary bonding layer 780a to support the light-emitting part 720a, the first ohmic electrode 730a, the passivation layer 750a, the contact electrode 760a, and the bonding pad layer 770a, and it is preferable that the final support substrate 790a be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 790a that meet these criteria may include sapphire, or glass that has been adjusted to have a difference in thermal expansion coefficient of 2 ppm or less from the initial growth substrate.

Meanwhile, in the present invention, the final support substrate 790a functions as a final support substrate that supports the light-emitting part 720a, the first ohmic electrode 730a, the passivation layer 750a, the contact electrode 760a, and the bonding pad layer 770a after the epitaxial die 700a of the present invention is finally completed. At this time, it is preferable that an LLO sacrificial separation layer (not shown), which is a functional material that can be easily separated and removed by an LLO technique in the process of the third operation S73, be formed between the final support substrate 790a and the temporary bonding layer 780a. The above-described LLO sacrificial separation layer (not shown) may be made of materials such as ZnO, ITO, IZO, IGO, IGZO, InGaN, InGaON, GaON, TiN, SiO2, and SiNx.

Accordingly, the epitaxial die 700a for a semiconductor light-emitting device according to the seventh embodiment of the present invention has a form in which the contact electrode 760a, which is a negative electrode, is interposed between the temporary bonding layer 780a and the light-emitting part 720a and thus is not exposed, and only the bonding pad layer 770a, which functions as a positive electrode, is exposed to the outside.

The second operation S72 is an operation of placing the epitaxial die 700a upside down on the first electrode pad 11aa, and electrically connecting the first electrode pad 11aa and the bonding pad layer 770a by bonding the first electrode pad 11aa and the bonding pad layer 770a through a bonding layer 12a. At this time, the placement and bonding of the epitaxial die 700a can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 700a, (2) an epitaxial die 700a with an ultra-small size of less than 50 μm×50 μm, and (3) an epitaxial die 700a having a self-assembly structure, additional masking media (such as a photoresist, ceramics (like glass, quartz, and alumina), or an invar FMM) or processes may be employed before the placement and bonding of the epitaxial die 700a.

The third operation S73 is an operation of separating the final support substrate 790a of the epitaxial die 700a. At this time, in the third operation S73, the final support substrate 790a may be separated from the temporary bonding layer 780a using an LLO technique. Here, the LLO technique is a technique of separating the final support substrate 790a from the temporary bonding layer 780a by irradiating a rear surface of the transparent final support substrate 790a with a UV laser beam having a uniform output and beam profile, and a single wavelength.

The fourth operation S74 is an operation of etching and removing the temporary bonding layer 780a to expose the contact electrode 760a.

Meanwhile, in the fourth operation S74, a mold part 14a surrounding the epitaxial die 700a may be formed before electrical defect inspection is performed in the fifth operation S75. At this time, the mold part 14a may be made of materials that enable LDS or LDI, allowing laser drilling in the sixth operation S76 to be described below. In addition, when the mold part 14a is not formed in the fourth operation S74, the contact electrode may be exposed after a photoresist (PR) is applied.

The fifth operation S75 is an operation of inspecting electrical defects of the epitaxial die 700a through the exposed contact electrode 760a, and repairing the semiconductor light-emitting device by replacing the corresponding epitaxial die 700a when the electrical defect inspection result indicates that the epitaxial die 700a is electrically defective. That is, in the present invention, electrical defects in the epitaxial die 700a can be detected and the defective epitaxial die 700a can be easily replaced before an upper wiring process is performed to form an extension electrode 13a.

The sixth operation S76 is an operation of forming the extension electrode 13a that electrically connects the second electrode pad 11ba and the contact electrode 760a. Meanwhile, when the mold part 14a is not formed in the fourth operation S74, the mold part 14a surrounding the epitaxial die 700a may be formed in the sixth operation S76, following the electrical defect inspection. That is, when the mold part 14a is formed after the electrical defect inspection in the fifth operation S75, there is an effect that the semiconductor light-emitting device is more easily repaired.

More specifically, in the sixth operation S76, laser drilling is used to etch the mold part 14a above the second electrode pad 11ba to form a through hole H, and the extension electrode 13a is formed to extend vertically from an upper portion of the second electrode pad 11ba to above the mold part 14a through the through hole H and then be bent toward the contact electrode 760a, thereby electrically connecting the contact electrode 760a and the second electrode pad 11ba.

The seventh operation S77 is an operation of forming a black matrix 15a that covers the extension electrode 13a and the mold part 14a. The black matrix 15a may be formed using photolithography and spin coating processes, but the present invention is not limited thereto.

In addition, the black matrix 15a may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, an epitaxial die 100b, which facilitates detection of electrical defects, according to an eighth embodiment of the present invention will be described in detail.

FIG. 23 illustrates an overall view of the epitaxial die that facilitates detection of electrical defects according to the eighth embodiment of the present invention, and FIG. 24 illustrates that the epitaxial die that facilitates detection of electrical defects according to the eighth embodiment of the present invention includes a sacrificial release layer and a bonding layer when emitting red light.

As shown in FIG. 23, the epitaxial die 100b, which facilitates detection of electrical defects, according to the eighth embodiment of the present invention includes a final support substrate 110b, a light-emitting part 120b, an ohmic electrode 130b, a passivation layer 150b, a contact electrode 160b, and a bonding pad layer 170b.

The final support substrate 110b supports the light-emitting part 120b, the ohmic electrode 130b, the passivation layer 150b, the contact electrode 160b, and the bonding pad layer 170b, and a sapphire initial growth substrate may be used thereas. The light-emitting part 120b, which will be described below, may be epitaxially grown on the initial growth substrate.

Meanwhile, in the present invention, the initial growth substrate on which the light-emitting part 120b is grown functions as the final support substrate 110b that supports the light-emitting part 120b, the first ohmic electrode 130b, the passivation layer 150b, the contact electrode 160b, and the bonding pad layer 170b after the epitaxial die 100b of the present invention is finally completed.

The light-emitting part 120b generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, may be epitaxially grown on the final support substrate 110b, which is an initial growth substrate, by being placed in appropriate positions and sequences.

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 120b includes a first semiconductor region 121b (e.g., a p-type semiconductor region), an active region 123b (e.g., MQWs), and a second semiconductor region 122b (e.g., an n-type semiconductor region), and the light-emitting part 120b may have a structure in which the second semiconductor region 122b, the active region 123b, and the first semiconductor region 121b are epitaxially grown in that order on the final support substrate 110b, and ultimately, may have an overall thickness typically ranging from about 5.0 to 8.0 μm, including multiple layers of group III nitrides, but the present invention is not limited thereto.

Each of the first semiconductor region 121b, the active region 123b, and the second semiconductor region 122b may be formed as either a single layer or multiple layers, and although not shown in the drawing, necessary layers, such as buffer regions, may be added before the light-emitting part 120b is epitaxially grown on the sapphire initial growth substrate to ensure the high quality of the epitaxially grown light-emitting part 120b. For example, the buffer regions may include a nucleation layer and a compliant layer composed of an un-doped semiconductor region to relieve stress and improve thin-film quality and typically have a thickness of about 4.0 μm. In addition, when the final support substrate 110b is removed using an LLO technique, a sacrificial layer may be provided between the nucleation layer and the un-doped semiconductor region, and a seed layer may function as the sacrificial layer.

The second semiconductor region 122b has a second conductivity type (n-type), and is formed on the final support substrate 110b. The second semiconductor region 122b may have a thickness of 2.0 to 3.5 μm.

The active region 123b generates light using the recombination of electrons and holes and is formed on the second semiconductor region 122b. The active region 123b may have a multi-layer structure primarily composed of indium gallium nitride (InGaN) and gallium nitride (GaN) semiconductors, and may have a thickness of several tens of nanometers (nm).

The first semiconductor region 121b has a first conductivity type (p-type), and is formed on the active region 123b. The first semiconductor region 121b may have a multi-layer structure primarily composed of aluminum gallium nitride (AlGaN) and gallium nitride (GaN) semiconductors, may have a thickness ranging from several tens of nanometers (nm) to several micrometers (μm), and includes a top surface having gallium (Ga) polarity.

That is, the active region 123b is interposed between the first semiconductor region 121b and the second semiconductor region 122b, and light is generated when holes in the first semiconductor region 121b, which is a p-type semiconductor region, and electrons in the second semiconductor region 122b, which is an n-type semiconductor region, recombine in the active region 123b.

At this time, the light-emitting part 120b formed on the final support substrate 110b may have side portions, i.e., one or both sides, etched to a predetermined depth (i.e., both side surfaces may have a mesa-etched shape), and when viewed from above, all of upper, lower, left, and right edges may have a mesa-etched shape. Here, the predetermined depth may refer to a depth up to the second semiconductor region 122b, but the present invention is not limited thereto. Meanwhile, the surface of the etched portion of the second semiconductor region 122b of the light-emitting part 120b has gallium (Ga) polarity.

The ohmic electrode 130b is electrically connected to the first semiconductor region 121b of the light-emitting part 120b and is formed on the first semiconductor region 121b to cover and come into surface contact with an upper surface of the first semiconductor region 121b. At this time, the first semiconductor region 121b is electrically connected to the ohmic electrode 130b through a p-ohmic contact.

The contact electrode 160b is electrically connected to the second semiconductor region 122b of the light-emitting part 120b, and may be formed at the etched side portion, i.e., one side or both sides, of the second semiconductor region 122b.

Meanwhile, when the etched portion of the light-emitting part 120b has a gallium (Ga) polar surface, to which the contact electrode 160b is electrically connected through an n-ohmic contact, there is an issue that the second semiconductor region 122b of the light-emitting part 120b must be excessively etched to expose the contact electrode 160b for electrical defect inspection during a transfer process.

Accordingly, the contact electrode 160b of the present invention has a bridge structure so that electrical defects can be easily detected, and more specifically, the contact electrode 160b includes a base part 161b and a bent part 162b formed to bend and extend from one end portion of the base part 161b and placed between the passivation layer 150b and the light-emitting part 120b.

The bent part 162b may have a stepped shape formed to bend and extend from the one end portion of the base part 161b in a direction opposite to the bonding pad layer 170b to facilitate the detection of electrical defects during the transfer process. At this time, the bent part 162b may be formed by bending multiple times as needed.

The ohmic electrode 130b and the contact electrode 160b may be formed of materials that essentially have high transparency and/or reflectance and excellent electrical conductivity, but the present invention is not limited thereto. The materials of the ohmic electrode 130b may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination.

Meanwhile, the materials of the contact electrode 160b may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, which may be used alone or in combination.

At this time, as described above, the etched portion of the second semiconductor region 122b has a gallium (Ga) polar surface, and the gallium (Ga) polar surface is electrically connected to the contact electrode 160b through an n-ohmic contact.

The passivation layer 150b covers a side portion of the ohmic electrode 130b from the etched portion of the light-emitting part 120b via the contact electrode 160b, and when both sides of the light-emitting part 120b are etched, the passivation layer may have a shape that covers one side of the ohmic electrode 130b from the etched portion on one side of the light-emitting part 120b via the contact electrode 160b, and covers the other side of the ohmic electrode 130b from the etched portion on the other side of the light-emitting part 120b via the contact electrode 160b. Due to such a shape of the passivation layer 150b, the contact electrode 160b is interposed between the passivation layer 150b and the light-emitting part 120b and thus is not exposed.

The passivation layer 150b may be implemented with electrically insulating materials, and may include, for example, a single layer or multiple layers including at least one material from among silicon oxide, silicon nitride, metallic oxides including Al₂O₃, and organic insulators.

The bonding pad layer 170b functions as a vertical chip die bonding pad, and is formed on the ohmic electrode 130b and the passivation layer 150b to be electrically connected to the ohmic electrode 130b. At this time, the bonding pad layer 170b is electrically connected to the ohmic electrode 130b through a p-ohmic contact and is exposed to the outside, thereby functioning as a positive electrode.

The bonding pad layer 170b may include a diffusion barrier layer made of high melting point metals (such as Cr, V, Ti, W, Mo, and Re), or metals with high atomic packing density (such as Pt and Ni), and may basically include low melting point metals and noble metals such as gold (Au), silver (Ag), copper (Cu), and palladium (Pd), but the present invention is not limited thereto. In addition, the low melting point metals of the bonding pad layer 170b may be formed of metals such as In, Sn, Zn, and Pb alone or alloys including these metals.

Accordingly, the epitaxial die 100b, which facilitates detection of electrical defects, according to the eighth embodiment of the present invention has a form in which the contact electrode 160b, which is a negative electrode, is interposed between the passivation layer 150b and the light-emitting part 120b, and thus is not exposed, and only the bonding pad layer 170b, which functions as a positive electrode, is exposed to the outside.

Meanwhile, as shown in FIG. 24, when the epitaxial die 100b, which facilitates detection of electrical defects, according to the eighth embodiment of the present invention emits red light, the epitaxial die 100b may further include a sacrificial release layer N and a bonding layer B.

When the epitaxial die 100b emits red light, the same sapphire final support substrate 110b may be used as the final support substrate 110b as when the epitaxial die 100b emits blue or green light, and the final support substrate 210b may support the light-emitting part 120b, the ohmic electrode 130b, the passivation layer 150b, the contact electrode 160b, and the bonding pad layer 170b.

In addition, when the epitaxial die 100b emits red light, in the light-emitting part 120b, binary, ternary, and quaternary compounds of Group III (Al, Ga, and In) phosphide semiconductors, such as indium phosphide (InP), indium gallium phosphide (InGaP), gallium phosphide (GaP), aluminum indium phosphide (AlInP), aluminum gallium phosphide (AlGaP), aluminum phosphide (AIP), and aluminum gallium indium phosphide (AlGaInP), may be placed in appropriate positions and sequences on an initial growth substrate and epitaxially grown.

In particular, in order to emit red light, a high-quality Group III phosphide semiconductor with a high indium (In) composition, such as indium gallium phosphide (InGaP), should preferentially be formed on top of Group III phosphide semiconductors composed of gallium phosphide (GaP), aluminum indium phosphide (AlInP), aluminum gallium phosphide (AlGaP), aluminum phosphide (AIP), and aluminum gallium indium phosphide (AlGaInP), but the present invention is not limited thereto.

In addition, the sacrificial release layer N may be made of materials such as ZnO, ITO, IZO, IGO, IGZO, InGaN, InGaON, GaON, TiN, SiO2, and SiNx, and the bonding layer B and a temporary bonding layer to be described below are preferentially selected from dielectric materials that do not undergo physical property changes and have excellent thermal conductivity in a metalorganic chemical vapor deposition (MOCVD) chamber (at temperatures greater than or equal to 1000° C. and in a reducing atmosphere), and may include, for example, silicon oxide (SiO2, 0.8 ppm), silicon nitride (SiNx, 3.8 ppm), silicon carbonitride (SiCN, 3.8 to 4.8 ppm), aluminum nitride (AlN, 4.6 ppm), and aluminum oxide (Al₂O₃, 6.8 ppm), and may also include flowable oxides (FOx), such as spin-on glass (SOG, liquid SiO2) and hydrogen silsesquioxane (HSQ), to improve surface roughness.

Meanwhile, when the epitaxial die 100b emits red light, a gallium arsenide (GaAs) initial growth substrate may be used as the initial growth substrate. After the sacrificial release layer N is formed on the GaAs initial growth substrate, the light-emitting part 120b that emits red light is epitaxially grown, and then the ohmic electrode 130b, the passivation layer 150b, the contact electrode 160b, and the bonding pad layer 170b are grown using similar deposition techniques.

Subsequently, after the sacrificial release layer N is formed on an intermediate temporary substrate, the intermediate temporary substrate is bonded to the bonding pad layer 170b through the temporary bonding layer. Thereafter, using a chemical lift-off (CLO) technique, the initial growth substrate is separated from the sacrificial release layer N, and the sacrificial release layer N below the light-emitting part 120b is etched and removed, thereby exposing a lower surface of the light-emitting part 120b. At this time, the intermediate temporary substrate may be made of the same sapphire substrate as the final support substrate 110b to minimize the difference in a coefficient of thermal expansion (CTE) between the intermediate temporary substrate and the final support substrate 110b.

Subsequently, after the sacrificial release layer N is formed on the sapphire final support substrate 110b, the final support substrate 110b is bonded to the lower surface of the light-emitting part 120b through the bonding layer B. Thereafter, using an LLO technique, the intermediate temporary substrate is separated from the sacrificial release layer N, and the sacrificial release layer N above the light-emitting part 120b is etched and removed, thereby exposing the bonding pad layer 170b and completing the structure as shown in FIG. 24 (i.e., a structure in which the final support substrate 110b, the sacrificial release layer N, the bonding layer B, and the laminate are sequentially stacked).

Hereinafter, with reference to the accompanying drawings, a method (S80) of manufacturing a semiconductor light-emitting device using the epitaxial die that facilitates detection of electrical defects according to the eighth embodiment of the present invention will be described in detail.

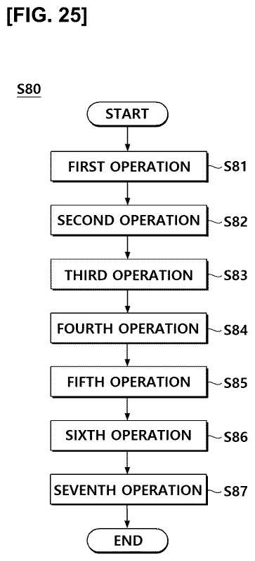

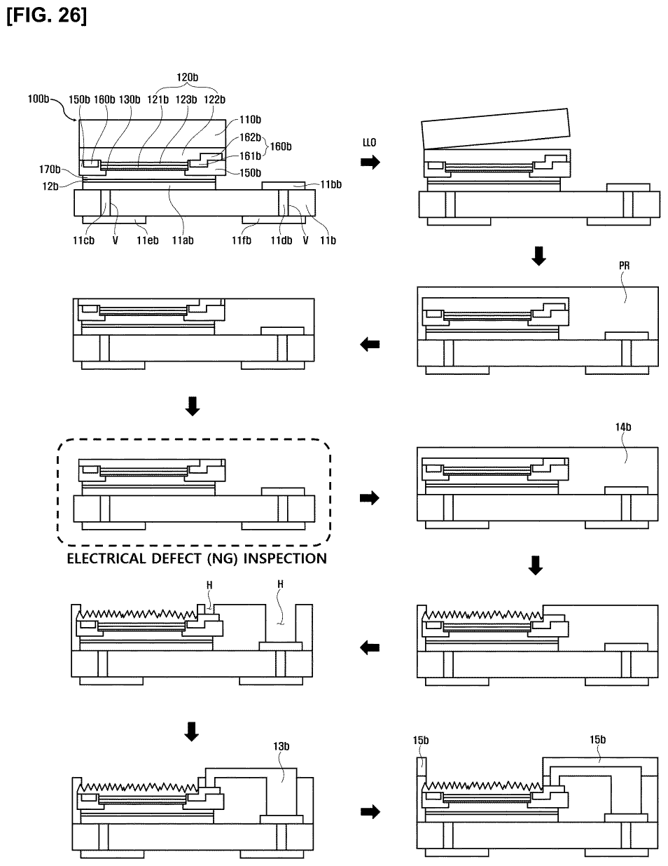

FIG. 25 is a flowchart illustrating the method of manufacturing the semiconductor light-emitting device using the epitaxial die that facilitates detection of electrical defects according to the eighth embodiment of the present invention, and FIG. 26 illustrates a process of manufacturing the semiconductor light-emitting device using the epitaxial die that facilitates detection of electrical defects according to the eighth embodiment of the present invention.

As shown in FIGS. 25 and 26, the method (S80) of manufacturing the semiconductor light-emitting device using the epitaxial die 100b, which facilitates detection of electrical defects, according to the eighth embodiment of the present invention includes a first operation S81, a second operation S82, a third operation S83, a fourth operation S84, a fifth operation S85, a sixth operation S86, and a seventh operation S87. However, it is of course possible to change the order of the processes shown in FIGS. 25 and 26.

The first operation S81 is an operation of preparing the epitaxial die 100b, which facilitates detection of electrical defects, according to the eighth embodiment of the present invention and a substrate part 11b.

The substrate part 11b supports the epitaxial die 100b that is bonded thereto, and a first electrode pad 11ab and a second electrode pad 11bb are formed on an upper surface of the substrate part 11b.

In addition, when the substrate part 11b has a first electrode post 11cb and a second electrode post 11db formed through via holes V formed therein, a first upper electrode pad 11ab electrically connected to the first electrode post 11cb at an upper portion of the first electrode post 11cb, a second upper electrode pad 11bb electrically connected to the second electrode post 11db at an upper portion of the second electrode post 11db, a first lower electrode pad 11eb electrically connected to the first electrode post 11cb at a lower portion of the first electrode post 11cb, and a second lower electrode pad 11fb electrically connected to the second electrode post 11db at a lower portion of the second electrode post 11dba may be formed.

Such a substrate part 11b may be a semiconductor wafer, a PCB, TFT glass, an interposer, or the like. Furthermore, the substrate part 11b may be a structure including through-silicon vias (TSVs), through-glass vias (TGVs), through-sapphire vias (TSaVs), through-AAO vias (TAVs), through-zirconia vias (TZVs), through-polyimide vias (TPoVs), and through-resin vias (TRVs), in which a plurality of via holes V are formed first, and then electrode posts 11cb and 11db are formed in the corresponding via holes V, but the present invention is not limited thereto.

Meanwhile, in the present invention, the first electrode pad 11ab may be provided as a plurality of individual electrodes, and the second electrode pad 11bb may be provided as a common electrode. When the first electrode pad 11ab is an individual negative electrode, the second electrode pad 11bb may be a common positive electrode, and when the first electrode pad 11ab is an individual positive electrode, the second electrode pad 11bb may be a common negative electrode, which may vary depending on the characteristics of the epitaxial die 100b (for example, the polarity of the bonding pad layer 170b).

The first electrode post 11cb and the second electrode post 11db may each be formed in the shape of a column (a post) in the via hole V that passes through the substrate part 11b, using copper (Cu) plating (or by inserting a nickel (Ni) wire), and in this case, the via hole V may be formed at each of four corner portions of the substrate part 11b to enhance a bonding strength of the substrate part 11b through a plurality of electrode posts 11cb and 11db. For example, when the epitaxial die 100b is transferred (placed) onto the substrate part 11b, three first electrode posts 11cb, which are individual electrodes, may be formed in the via holes V at the corner portions of the substrate part 11b, while one second electrode post 11db, which is a common electrode, may be formed in the via hole V at the remaining corner of the substrate part 11b. Subsequently, the first electrode post 11cb may be electrically connected to the bonding pad layer 170b of the epitaxial die 100b, and the second electrode post 11db may be electrically connected to the contact electrode 160b of the epitaxial die 100b through an extension electrode 13b, which will be described below.

In addition, the epitaxial die 100b, which facilitates detection of electrical defects, according to the eighth embodiment of the present invention includes a support substrate 110b, a light-emitting part 120b that generates light, an ohmic electrode 130b, a passivation layer 150b, a bent part 162b formed to bend and extend from one end portion thereof, a contact electrode 160b that is not exposed to the outside, and a bonding pad layer 170b that is exposed to the outside.

Here, the support substrate 110b, the light-emitting part 120b, the ohmic electrode 130b, the passivation layer 150b, the contact electrode 160b, and the bonding pad layer 170b are the same as those of the above-described epitaxial die 100b, which facilitates detection of electrical defects, according to the eighth embodiment of the present invention, and thus redundant descriptions will be omitted.

The second operation S82 is an operation of placing the epitaxial die 100b upside down on the first upper electrode pad 11ab, and electrically connecting the first upper electrode pad 11ab and the bonding pad layer 170b by bonding the first upper electrode pad 11ab and the bonding pad layer 170b through a bonding layer 12b. At this time, the placement and bonding of the epitaxial die 100b can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 100b, (2) an epitaxial die 100b with an ultra-small size of less than 50 μm×50 μm, and (3) an epitaxial die 100b having a self-assembly structure, additional masking media (such as a photoresist, ceramics (like glass, quartz, and alumina), or an invar fine metal mask (FMM)) or processes may be employed before the placement and bonding of the epitaxial die 100b.

The third operation S83 is an operation of separating the final support substrate 110b of the epitaxial die 100b. At this time, in the third operation S83, the final support substrate 110b may be separated from the light-emitting part 120b, i.e., the second semiconductor region 122b, using an LLO technique to expose an upper surface of the second semiconductor region 122b. Here, the LLO technique is a technique of separating the final support substrate 110b from the epitaxially grown layers by irradiating a rear surface of the transparent final support substrate 110b with a UV laser beam having a uniform output and beam profile, and a single wavelength.

The fourth operation S84 is an operation of etching the upper surface of the second semiconductor region 122b of the light-emitting part 120b to expose the bent part 162b of the contact electrode 160b.

At this time, in the fourth operation S84, a photoresist (PR) may be applied to surround the epitaxial die 100b, and the applied photoresist (PR) may be removed after the bent part 162b is exposed.

Meanwhile, in the fourth operation S84, a surface texture pattern of a predetermined shape or an irregular shape may be formed on the upper surface of the light-emitting part 120b, i.e., the upper surface of the second semiconductor region 122b, of the upside-down epitaxial die 100b to extract as much light generated in the active region 123b into the air as possible.

The fifth operation S85 is an operation of inspecting electrical defects of the epitaxial die 100b through the exposed bent part 162b, and repairing the semiconductor light-emitting device by replacing the corresponding epitaxial die 100b when the electrical defect inspection result indicates that the epitaxial die 100b is electrically defective. That is, in the present invention, electrical defects in the epitaxial die 100b can be detected and the defective epitaxial die 100b can be easily replaced before an upper wiring process is performed to form the extension electrode 13b.

The sixth operation S86 is an operation of forming a mold part 14b that surrounds the epitaxial die 100b, etching the mold part 14b to expose the second electrode pad 11bb and the bent part 162b, and then forming the extension electrode 13b that electrically connects the exposed second electrode pad 11bb and bent part 162b.

More specifically, in the sixth operation S86, laser drilling is used to etch the mold part 14b above the second electrode pad 11bb to form a through hole H above the second electrode pad 11bb, and when necessary, the mold part 14b above the bent part 162b is etched to form a through hole H above the bent part 162b. Subsequently, in the sixth operation S86, the extension electrode 13b that electrically connects the second electrode pad 11bb and the exposed bent part 162b is formed, and the extension electrode 13b may have a shape that is formed to extend vertically from an upper portion of the second electrode pad 11bb to above the mold part 14b through the through hole H, then be bent and extend laterally toward the bent part 162b, and finally be bent vertically to extend toward and come into contact with the exposed bent part 162b.

The seventh operation S87 is an operation of forming a black matrix 15b that covers the extension electrode 13b and the mold part 14b. The black matrix 15b may be formed using photolithography and spin coating processes, but the present invention is not limited thereto.

In addition, the black matrix 15b may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, an epitaxial die 200b, which facilitates detection of electrical defects, according to a ninth embodiment of the present invention will be described in detail.

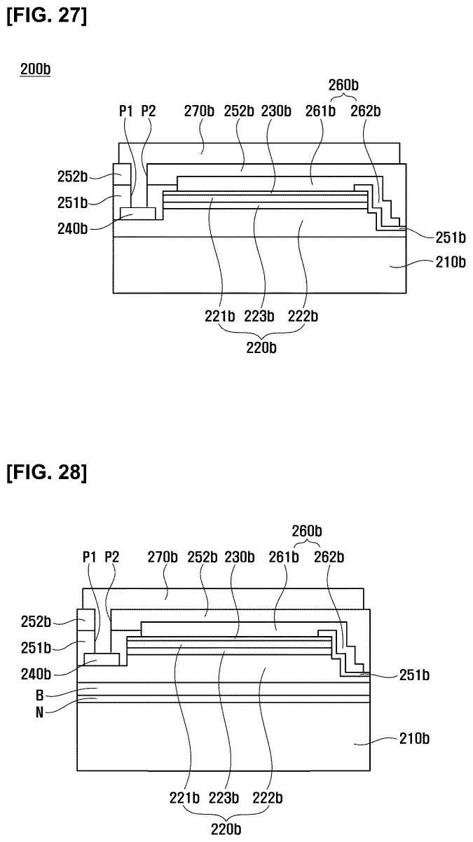

FIG. 27 illustrates an overall view of the epitaxial die that facilitates detection of electrical defects according to the ninth embodiment of the present invention, and FIG. 28 illustrates that the epitaxial die that facilitates detection of electrical defects according to the ninth embodiment of the present invention includes a sacrificial release layer and a bonding layer when emitting red light.

As shown in FIG. 27, the epitaxial die 200b, which facilitates detection of electrical defects, according to the ninth embodiment of the present invention includes a final support substrate 210b, a light-emitting part 220b, a first ohmic electrode 230b, a second ohmic electrode 240b, a first passivation layer 251b, a contact electrode 260b, a second passivation layer 252b, and a bonding pad layer 270b.

The final support substrate 210b supports the light-emitting part 220b, the first ohmic electrode 230b, the second ohmic electrode 240b, the first passivation layer 251b, the contact electrode 260b, the second passivation layer 252b, and the bonding pad layer 270b, and a sapphire initial growth substrate may be used thereas. The light-emitting part 220b to be described below may be epitaxially grown on the initial growth substrate.

Meanwhile, in the present invention, the initial growth substrate on which the light-emitting part 220b is grown functions as the final support substrate 210b that supports the light-emitting part 220b, the first ohmic electrode 230b, the second ohmic electrode 240b, the first passivation layer 251b, the contact electrode 260b, the second passivation layer 252b, and the bonding pad layer 270b after the epitaxial die 200b of the present invention is finally completed.

The light-emitting part 220b generates light, and details of a first semiconductor region 221b, a second semiconductor region 222b, and an active region 223b are the same as those of the above-described epitaxial die 100b, which facilitates detection of electrical defects, according to the eighth embodiment of the present invention, and thus redundant descriptions will be omitted.

At this time, one side of the light-emitting part 220b formed on the final support substrate 210b may have a shape etched to a predetermined depth (i.e., one side may have a mesa-etched shape), and here, the predetermined depth may refer to a depth up to the second semiconductor region 222b, but the present invention is not limited thereto. Meanwhile, the surface of the etched portion of the second semiconductor region 222b of the light-emitting part 220b has gallium (Ga) polarity.

The first ohmic electrode 230b is electrically connected to the first semiconductor region 221b of the light-emitting part 220b and is formed on the first semiconductor region 221b to cover and come into surface contact with an upper surface of the first semiconductor region 221b. At this time, the first semiconductor region 221b is electrically connected to the first ohmic electrode 230b through a p-ohmic contact.

The second ohmic electrode 240b is electrically connected to the second semiconductor region 222b of the light-emitting part 220b and is formed at the etched portion on one side of the second semiconductor region 222b.

The first ohmic electrode 230b and the second ohmic electrode 240b may be formed of materials that essentially have high transparency and/or reflectance and excellent electrical conductivity, but the present invention is not limited thereto. The materials of the first ohmic electrode 230b may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au may be used alone or in combination with the above-described optically transparent materials. Meanwhile, the materials of the second ohmic electrode 240b may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, which may be used alone or in combination with above-described metals.

At this time, as described above, the etched portion of the second semiconductor region 222b has a gallium (Ga) polar surface, and the gallium (Ga) polar surface is electrically connected to the second ohmic electrode 240b through an n-ohmic contact.

The first passivation layer 251b covers one side of the first ohmic electrode 230b from the etched portion on one side of the light-emitting part 220b via the second ohmic electrode 240b, and covers the other side of the first ohmic electrode 230b from the other side of the light-emitting part 220b. The first passivation layer 251b may have a shape that covers one side and the other side of the first ohmic electrode 230b and may thus have a shape that exposes a portion of the first ohmic electrode 230b.

The first passivation layer 251b may be implemented with electrically insulating materials, and may include, for example, a single layer or multiple layers including at least one material from among silicon oxide, silicon nitride, metallic oxides including Al₂O₃, and organic insulators.

The contact electrode 260b is electrically connected to the first ohmic electrode 230b and is formed on the first ohmic electrode 230b exposed between gaps in the first passivation layer 251b.

Meanwhile, when the etched portion of the light-emitting part 220b has a gallium (Ga) polar surface, to which the second ohmic electrode 240b is electrically connected through an n-ohmic contact, there is an issue that the second semiconductor region 222b of the light-emitting part 220b must be excessively etched to expose the contact electrode 260b for electrical defect inspection during a transfer process.

Accordingly, the contact electrode 260b of the present invention has a bridge structure so that electrical defects can be easily detected, and more specifically, the contact electrode 260b includes a base part 261b and a bent part 262b formed to bend and extend from one end portion of the base part 261b and placed between the first passivation layer 251b and the second passivation layer 252b.

The bent part 262b may be formed to bend and extend from one end portion (i.e., the side opposite to where the second ohmic electrode 240b is formed) of the base part 261b, and have a stepped shape formed to bend and extend in a direction opposite to the bonding pad layer 270b to facilitate the detection of electrical defects during the transfer process. At this time, the bent part 262b may be formed by bending multiple times as needed.

The materials of the contact electrode 260b are not limited as long as they have strong adhesion to the first ohmic electrode 230b, but may include Ti, TiN, Cr, CrN, V, VN, NiCr, Al, Rh, Pt, Ni, Pd, Ru, Cu, Ag, Au, and the like.

The second passivation layer 252b covers the first passivation layer 251b and the contact electrode 260b, and here, an end portion on the other side (i.e., the side opposite to where the second ohmic electrode 240b is formed) of the contact electrode 260b may be partially etched, and the second passivation layer 252b may cover the one end portion of the contact electrode 260b from the etched portion of the other end portion of the contact electrode 260b via the contact electrode 260b to prevent the contact electrode 260b from being exposed to the outside. Due to the shape of the second passivation layer 252b that encloses the contact electrode 260b in this manner, the contact electrode 260b is interposed between the second passivation layer 252b and the first ohmic electrode 230b and thus is not exposed.

The second passivation layer 252b may be implemented with electrically insulating materials, and include, for example, a single layer or multiple layers including at least one material from among silicon oxide, silicon nitride, metallic oxides including Al₂O₃, and organic insulators.

The bonding pad layer 270b functions as a vertical chip die bonding pad, and is formed on the second passivation layer 252b to be electrically connected to the second ohmic electrode 240b. At this time, the bonding pad layer 270b is electrically connected to the second ohmic electrode 240b, is exposed to the outside, and functions as a negative electrode.

The bonding pad layer 270b may include a diffusion barrier layer made of high melting point metals (such as Cr, V, Ti, W, Mo, and Re), or metals with high atomic packing density (such as Pt and Ni), and may basically include low melting point metals and noble metals such as gold (Au), silver (Ag), copper (Cu), and palladium (Pd), but the present invention is not limited thereto. In addition, the low melting point metals of the bonding pad layer 270b may be formed of metals such as In, Sn, Zn, and Pb alone or alloys including these metals.

Meanwhile, a first through hole P1 is formed in the first passivation layer 251b above the second ohmic electrode 240b to expose the second ohmic electrode 240b, and a second through hole P2 in communication with the first through hole P1 is formed in the second passivation layer 252b. The bonding pad layer 270b may be electrically connected to the second ohmic electrode 240b through the first through hole P1 and the second through hole P2.

Accordingly, in the epitaxial die 200b, which facilitates detection of electrical defects, according to the ninth embodiment of the present invention, the contact electrode 260b serving as a positive electrode and the first ohmic electrode 230b are interposed between the second passivation layer 252b and the light-emitting part 220b and thus are not exposed, and only the bonding pad layer 270b functioning as a negative electrode is exposed to the outside.

Meanwhile, as shown in FIG. 28, when the epitaxial die 200b, which facilitates detection of electrical defects, according to the ninth embodiment of the present invention emits red light, the epitaxial die 200b may further include a sacrificial release layer N and a bonding layer B. When the epitaxial die 200b emits red light, the same sapphire final support substrate 210b may be used as the final support substrate 210b as when the epitaxial die 200b emits blue or green light, and the final support substrate 210b may support the light-emitting part 220b, the first ohmic electrode 230b, the second ohmic electrode 240b, the first passivation layer 251b, the contact electrode 260b, the second passivation layer 252b, and the bonding pad layer 270b.

In addition, when the epitaxial die 200b emits red light, in the light-emitting part 220b, binary, ternary, and quaternary compounds of Group III (Al, Ga, and In) phosphide semiconductors, such as indium phosphide (InP), indium gallium phosphide (InGaP), gallium phosphide (GaP), aluminum indium phosphide (AlInP), aluminum gallium phosphide (AlGaP), aluminum phosphide (AIP), and aluminum gallium indium phosphide (AlGaInP), may be placed in appropriate positions and sequences on an initial growth substrate and epitaxially grown.

In particular, in order to emit red light, a high-quality Group III phosphide semiconductor with a high indium (In) composition, such as indium gallium phosphide (InGaP), should preferentially be formed on top of Group III phosphide semiconductors composed of gallium phosphide (GaP), aluminum indium phosphide (AlInP), aluminum gallium phosphide (AlGaP), aluminum phosphide (AIP), and aluminum gallium indium phosphide (AlGaInP), but the present invention is not limited thereto.

In addition, the sacrificial release layer N may be made of materials such as ZnO, ITO, IZO, IGO, IGZO, InGaN, InGaON, GaON, TiN, SiO2, and SiNx, and the bonding layer B and a temporary bonding layer to be described below are preferentially selected from dielectric materials that do not undergo physical property changes and have excellent thermal conductivity in a metalorganic chemical vapor deposition (MOCVD) chamber (at temperatures greater than or equal to 1000° C. and in a reducing atmosphere), and may include, for example, silicon oxide (SiO2, 0.8 ppm), silicon nitride (SiNx, 3.8 ppm), silicon carbonitride (SiCN, 3.8 to 4.8 ppm), aluminum nitride (AlN, 4.6 ppm), and aluminum oxide (Al₂O₃, 6.8 ppm), and may also include flowable oxides (FOX), such as spin-on glass (SOG, liquid SiO2) and hydrogen silsesquioxane (HSQ), to improve surface roughness.

Meanwhile, when the epitaxial die 200b emits red light, a gallium arsenide (GaAs) initial growth substrate may be used as the initial growth substrate. After a sacrificial release layer N is formed on the GaAs initial growth substrate, the light-emitting part 220b that emits red light is epitaxially grown, and then the first ohmic electrode 230b, the second ohmic electrode 240b, the first passivation layer 251b, the contact electrode 260b, the second passivation layer 252b, and the bonding pad layer 270b are grown using similar deposition techniques.

Subsequently, after the sacrificial release layer N is formed on the intermediate temporary substrate, the intermediate temporary substrate is bonded to the bonding pad layer 270b through a temporary bonding layer. Thereafter, using a CLO technique, the initial growth substrate is separated from the sacrificial release layer N, and the sacrificial release layer N below the light-emitting part 220b is etched and removed, thereby exposing a lower surface of the light-emitting part 220b. At this time, the intermediate temporary substrate may be made of the same sapphire substrate as the final support substrate 210b to minimize the difference in a coefficient of thermal expansion (CTE) between the intermediate temporary substrate and the final support substrate 210b.

Subsequently, after the sacrificial release layer N is formed on the sapphire final support substrate 210b, the final support substrate 210b is bonded to the lower surface of the light-emitting part 220b through the bonding layer B. Thereafter, using an LLO technique, the intermediate temporary substrate is separated from the sacrificial release layer N, and the sacrificial release layer N above the light-emitting part 220b is etched and removed, thereby exposing the bonding pad layer 270b and completing the structure as shown in FIG. 28 (i.e., a structure in which the final support substrate 210b, the sacrificial release layer N, the bonding layer B, and the laminate are sequentially stacked).

Hereinafter, with reference to the accompanying drawings, a method (S90) of manufacturing a semiconductor light-emitting device using the epitaxial die 200b, which facilitates detection of electrical defects, according to the ninth embodiment of the present invention will be described in detail.

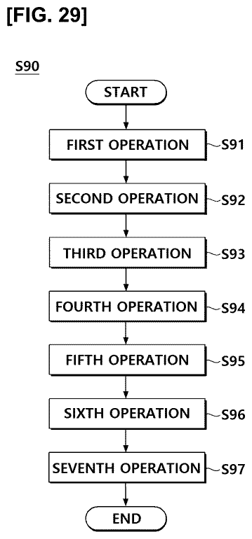

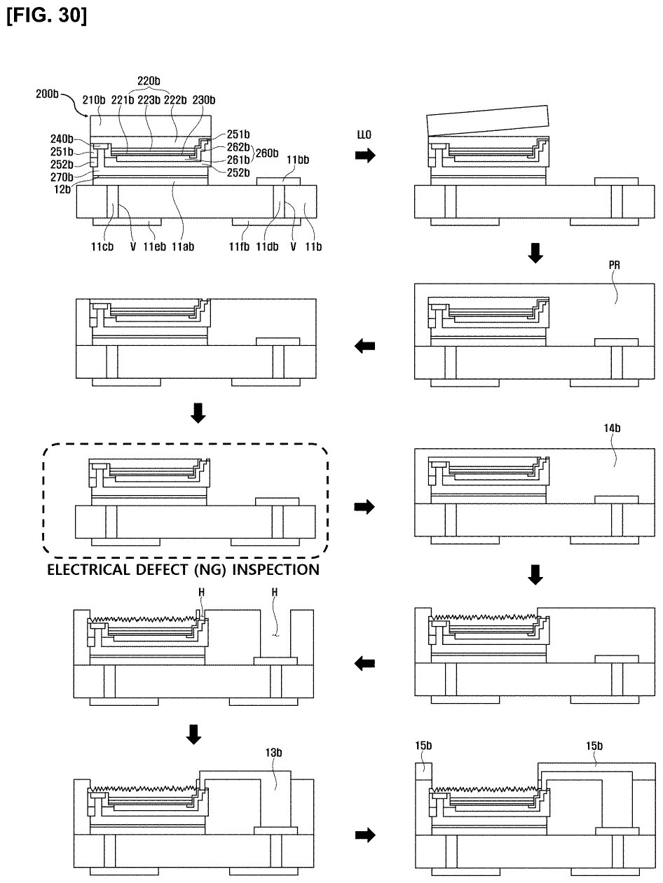

FIG. 29 is a flowchart illustrating the method of manufacturing the semiconductor light-emitting device using the epitaxial die 200b, which facilitates detection of electrical defects, according to the ninth embodiment of the present invention, and FIG. 30 illustrates a process of manufacturing the semiconductor light-emitting device using the epitaxial die 200b, which facilitates detection of electrical defects, according to the ninth embodiment of the present invention.

As shown in FIGS. 29 and 30, the method (S90) of manufacturing the semiconductor light-emitting device using the epitaxial die 200b, which facilitates detection of electrical defects, according to the ninth embodiment of the present invention includes a first operation S91, a second operation S92, a third operation S93, a fourth operation S94, a fifth operation S95, a sixth operation S96, and a seventh operation S97. However, it is of course possible to change the order of the processes shown in FIGS. 29 and 30.

The first operation S91 is an operation of preparing the epitaxial die 200b, which facilitates detection of electrical defects, according to the ninth embodiment of the present invention and a substrate part 11b.

The substrate part 11b supports the epitaxial die 200b that is bonded thereto, and a first electrode pad 11ab and a second electrode pad 11bb are formed on an upper surface of the substrate part 11b.

In addition, when the substrate part 11b has a first electrode post 11cb and a second electrode post 11db formed through via holes V formed therein, a first upper electrode pad 11ab electrically connected to the first electrode post 11cb at an upper portion of the first electrode post 11cb, a second upper electrode pad 11bb electrically connected to the second electrode post 11db at an upper portion of the second electrode post 11db, a first lower electrode pad 11eb electrically connected to the first electrode post 11cb at a lower portion of the first electrode post 11cb, and a second lower electrode pad 11fb electrically connected to the second electrode post 11db at a lower portion of the second electrode post 11dba may be formed.

Such a substrate part 11b may be a semiconductor wafer, a PCB, TFT glass, an interposer, or the like. Furthermore, the substrate part 11b may be a structure including through-silicon vias (TSVs), through-glass vias (TGVs), through-sapphire vias (TSaVs), through-AAO vias (TAVs), through-zirconia vias (TZVs), through-polyimide vias (TPoVs), and through-resin vias (TRVs), in which a plurality of via holes V are formed first, and then electrode posts 11cb and 11db are formed in the corresponding via holes V, but the present invention is not limited thereto.

Meanwhile, in the present invention, the first electrode pad 11ab may be provided as a plurality of individual electrodes, and the second electrode pad 11bb may be provided as a common electrode. When the first electrode pad 11ab is an individual negative electrode, the second electrode pad 11bb may be a common positive electrode, and when the first electrode pad 11ab is an individual positive electrode, the second electrode pad 11bb may be a common negative electrode, which may vary depending on the characteristics of the epitaxial die 200b (for example, the polarity of the bonding pad layer 270b).

The first electrode post 11cb and the second electrode post 11db may each be formed in the shape of a column (a post) in the via hole V that passes through the substrate part 11b, using copper (Cu) plating (or by inserting a nickel (Ni) wire), and in this case, the via hole V may be formed at each of four corner portions of the substrate part 11b to enhance a bonding strength of the substrate part 11b through a plurality of electrode posts 11cb and 11db. For example, when the epitaxial die 200b is transferred (placed) onto the substrate part 11b, three first electrode posts 11cb, which are individual electrodes, may be formed in the via holes V at the corner portions of the substrate part 11b, while one second electrode post 11db, which is a common electrode, may be formed in the via hole V at the remaining corner of the substrate part 11b. Subsequently, the first electrode post 11cb may be electrically connected to the bonding pad layer 270b of the epitaxial die 200b, and the second electrode post 11db may be electrically connected to the contact electrode 260b of the epitaxial die 200b through an extension electrode 13b, which will be described below.

In addition, the epitaxial die 200b, which facilitates detection of electrical defects, according to the ninth embodiment of the present invention includes the final support substrate 210b, a light-emitting part 220b that generates light, a first ohmic electrode 230b, a second ohmic electrode 240b, a first passivation layer 251b, a bent part 262b formed to bend and extend from one end portion thereof, a contact electrode 260b that is not exposed to the outside, a second passivation layer 252b, and a bonding pad layer 270b that is exposed to the outside.

Here, the final support substrate 210b, the light-emitting part 220b, the first ohmic electrode 230b, the second ohmic electrode 240b, the first passivation layer 251b, the contact electrode 260b, the second passivation layer 252b, and the bonding pad layer 270b are the same as those of the above-described epitaxial die 200b, which facilitates detection of electrical defects, according to the eighth embodiment of the present invention, and thus redundant descriptions will be omitted.

The second operation S92 is an operation of placing the epitaxial die 200b upside down on the first upper electrode pad 11ab, and electrically connecting the first upper electrode pad 11ab and the bonding pad layer 270b by bonding the first upper electrode pad 11ab and the bonding pad layer 270b through a bonding layer 12b. At this time, the placement and bonding of the epitaxial die 200b can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 200b, (2) an epitaxial die 200b with an ultra-small size of less than 50 μm×50 μm, and (3) an epitaxial die 200b having a self-assembly structure, additional masking media (such as a photoresist, ceramics (like glass, quartz, and alumina), or an invar FMM) or processes may be employed before the placement and bonding of the epitaxial die 200b.

The third operation S93 is an operation of separating the final support substrate 210b of the epitaxial die 200b. At this time, in the third operation S93, the final support substrate 210b may be separated from the light-emitting part 220b, i.e., the second semiconductor region 222b, using an LLO technique to expose an upper surface of the second semiconductor region 222b. Here, the LLO technique is a technique of separating the final support substrate 210b from the epitaxially grown layers by irradiating a rear surface of the transparent final support substrate 210b with a UV laser beam having a uniform output and beam profile, and a single wavelength.

The fourth operation S94 is an operation of etching the other side of the light-emitting part 220b (that is, the side opposite to where the second ohmic electrode 240b is formed) to expose the first passivation layer 251b, and then etching the exposed first passivation layer 251b to expose the bent part 262b of the contact electrode 260b.

At this time, in the fourth operation S94, a photoresist (PR) may be applied to surround the epitaxial die 200b, and the applied photoresist (PR) may be removed after the bent part 262b is exposed.

Meanwhile, in the fourth operation S94, a surface texture pattern of a predetermined shape or an irregular shape may be formed on the upper surface of the light-emitting part 220b, i.e., the upper surface of the second semiconductor region 222b, of the upside-down epitaxial die 200b to extract as much light generated in the active region 223b into the air as possible.

The fifth operation S95 is an operation of inspecting electrical defects of the epitaxial die 200b through the exposed bent part 262b, and repairing the semiconductor light-emitting device by replacing the corresponding epitaxial die 200b when the electrical defect inspection result indicates that the epitaxial die 200b is electrically defective. That is, in the present invention, electrical defects in the epitaxial die 200b can be detected and the defective epitaxial die 200b can be easily replaced before an upper wiring process is performed to form the extension electrode 13b.

The sixth operation S96 is an operation of forming a mold part 14b that surrounds the epitaxial die 200b, etching the mold part 14b to expose the second electrode pad 11bb and the bent part 262b, and then forming the extension electrode 13b that electrically connects the exposed second electrode pad 11bb and bent part 262b.

More specifically, in the sixth operation S96, laser drilling is used to etch the mold part 14b above the second electrode pad 11bb to form a through hole H above the second electrode pad 11bb, and when necessary, the first passivation layer 251b and the mold part 14b above the bent part 262b are etched to form a through hole H above the bent part 262b. Subsequently, in the sixth operation S96, the extension electrode 13b that electrically connects the second electrode pad 11bb and the exposed bent part 262b is formed, and the extension electrode 13b may have a shape that is formed to extend vertically from an upper portion of the second electrode pad 11bb to above the mold part 14b through the through hole H, then be bent and extend laterally toward the bent part 262b, and finally be bent vertically to extend toward and come into contact with the exposed bent part 262b.

The seventh operation S97 is an operation of forming a black matrix 15b that covers the extension electrode 13b and the mold part 14b. The black matrix 15b may be formed using photolithography and spin coating processes, but the present invention is not limited thereto.

In addition, the black matrix 15b may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Although all the components constituting the embodiments of the present invention have been described as being combined or combined to operate as one, the present invention is not necessarily limited to the embodiments. That is, one or more of all the components may be combined to operate as one within the scope of the present invention.

Further, since terms such as “comprising,” “including,” or “having” may mean that the corresponding component can be included unless otherwise stated, it should be construed that other components are not excluded but may be further included. Unless defined otherwise, all terms used herein, including technical or scientific terms, have the same meanings as those generally understood by those skilled in the art to which the present invention pertains. Commonly used terms, such as terms defined in dictionaries, should be interpreted as being consistent with the contextual meaning of the related art and are not interpreted with ideal or excessively formal meanings unless explicitly defined herein.

In addition, the above description is merely an exemplary description of the technical spirit of the present invention, and the present invention may be subjected to various modifications and variations made by those skilled in the art to which the present invention pertains without departing from the essential features of the present invention.

Accordingly, the embodiments disclosed in the present invention are not provided to limit the technical spirit of the embodiments of the present invention but are provided to describe the present invention, and the scope of the technical spirit of the present invention is not limited by the embodiments. The scope of protection of the present invention should be construed from the attached claims, and all the technical ideas within the equivalent ranges fall within the scope of the present invention.

1. (canceled)

2. A semiconductor light-emitting device using an epitaxial die that facilitates detection of electrical defects, wherein the epitaxial die is formed by separating into die units, and is formed as a semi-finished product in which only one of the two electrodes is exposed to the outside, and functions as a pixel after being individually transferred to a substrate part, comprising:
a substrate part in which a first electrode post and a second electrode post are formed through via holes, and a first electrode pad electrically connected to the first electrode post and a second electrode pad electrically connected to the second electrode post are formed on its upper surface;
a plurality of epitaxial dies including a light-emitting part that generates light, a passivation layer covering a portion of the light-emitting part, a contact electrode exposed to the outside after being transferred onto the substrate part, and a bonding pad layer arranged on the lower side of the light-emitting part and functioning as a vertical chip bonding pad;
a bonding layer that bonds and electrically connects a plurality of first electrode pads and a plurality of bonding pad layers of epitaxial dies;
an extension electrode that electrically connects the second electrode pad and the contact electrode exposed to the outside; and
a mold part that surrounds a plurality of epitaxial dies and extension electrodes, and exposes the upper surface of the extension electrodes,
wherein the via holes are formed at each corner of the substrate part to penetrate the substrate part,
wherein the mold part is formed so that its upper surface is lower than the upper surface of the extension electrode,
wherein the first electrode pad is formed in plurality, each of which functions as an individual electrode for the plurality of epitaxial dies, and is electrically connected to a plurality of first electrode posts,
wherein the second electrode pad is formed singularly, and functions as a common electrode for the plurality of epitaxial dies, and is electrically connected to the single second electrode post.

3. A method of manufacturing a semiconductor light-emitting device using an epitaxial die that facilitates detection of electrical defects, wherein the epitaxial die is formed by separating into die units, and is formed as a semi-finished product in which only one of the two electrodes is exposed to the outside, and functions as a pixel after being individually transferred to a substrate part, comprising:
a first operation of preparing a substrate part in which a first electrode post and a second electrode post are formed through via holes, and a first electrode pad electrically connected to the first electrode post and a second electrode pad electrically connected to the second electrode post are formed on its upper surface, and preparing a plurality of epitaxial dies including a light-emitting part that generates light, a passivation layer covering a portion of the light-emitting part, a contact electrode that is not exposed to the outside, and a bonding pad layer arranged on the lower side of the light-emitting part so as to be exposed to the outside and functioning as a vertical chip bonding pad;
a second operation of placing the plurality of epitaxial dies on the plurality of first electrode pads respectively, and bonding and electrically connecting the plurality of first electrode pads and the plurality of bonding pad layers of the plurality of epitaxial dies through a bonding layer;
a third operation of separating the support substrate;
a fourth operation of forming a mold part surrounding a plurality of the epitaxial dies, and exposing upper surface of the contact electrode; and
a fifth operation of etching the mold part to expose the second electrode pad, and forming an extension electrode that electrically connects the exposed second electrode pad and the exposed contact electrode, wherein the extension electrode is exposed to the outside,
wherein the via holes are formed at each corner of the substrate part to penetrate the substrate part,
wherein the mold part is formed so that its upper surface is lower than the upper surface of the extension electrode,
wherein the first electrode pad is formed in plurality, each of which functions as an individual electrode for the plurality of epitaxial dies, and is electrically connected to a plurality of first electrode posts,
wherein the second electrode pad is formed singularly, and functions as a common electrode for the plurality of epitaxial dies, and is electrically connected to the single second electrode post.

4-6. (canceled)

7. The semiconductor light-emitting device of claim 2, wherein the semiconductor light-emitting device further includes a black matrix covering the extension electrode and mold part.

8. The method of claim 3, wherein the method of manufacturing a semiconductor light-emitting device further includes a sixth operation of forming a black matrix covering the extension electrode and mold part.
